(19) United States
(12) Patent Application Publication
(10) Pub. No.: US 2025/0319669 A1
(43) Pub. Date: Oct. 16, 2025

(54) METHODS FOR FORMING WELDS BETWEEN THERMOPLASTIC MATERIALS

(71) Applicant: Board of Trustees of Michigan State University, East Lansing, MI (US)

(72) Inventors: Brian P. JOHNSON, Lansing, MI (US); Jacob I. REYNOLDS, Lansing, MI (US); Dhruv K. SINGH, East Lansing, MI (US)

(21) Appl. No.: 19/176,811

(22) Filed: Apr. 11, 2025

Related U.S. Application Data
(60) Provisional application No. 63/633,081, filed on Apr. 12, 2024.

(51) Int. Cl. B29C 65/00; B29C 65/16; B29C 65/78

(52) U.S. Cl. CPC B29C 66/73921; B29C 65/1619; B29C 65/7847

(57) ABSTRACT

A method for forming a weld between two thermoplastic materials includes contacting a laser to a precursor thermoplastic assembly including a thermoplastic plate and a thermoplastic sheet in direct contact with a first surface of the thermoplastic plate to cause localized melting at an interface between the first thermoplastic material layer and the second thermoplastic material layer, where the first and second thermoplastic material layers are opaque to the laser. The laser has a speed greater than or equal to about 0.05 m/s to less than or equal to about 0.2 m/s, a power greater than or equal to about 14 W to less than or equal to about 43 W, and a density greater than or equal to about 9,800 pulses per meter to less than or equal to about 29,600 pulses per meter.

### CROSS-REFERENCE TO RELATED APPLICATIONS

This application claims the benefit of U.S. Provisional Application No. 63/633,081 filed on Apr. 12, 2024. The entire disclosure of the above application is incorporated herein by reference.

### FIELD

The present disclosure relates to microfluidic plates and methods for preparing the same.

### BACKGROUND

This section provides background information related to the present disclosure which is not necessarily prior art.

Throughput-compatible and adaptable manufacturing techniques are crucial to addressing the growing need for new approach methods in drug and chemical screening as animal models are replaced. Manufacturing devices from traditional thermoplastics using additive processes (e.g., three-dimensional printing) or subtractive processes (e.g., computer numerical control (CNC) machining) often require additional bonding steps where a more optically transparent material (in the visible spectrum) is attached on a surface or face of the prepared device to seal the device and facilitate higher-resolution imaging. Computer numerical control microplate machining that machines devices directly into or onto ANSI/SLAS thermoplastic microplates may allow the machined devices to be easily integrate into existing infrastructure and avoids incompatible materials and is one promising technique. Bonding techniques for thermoplastics including computer numerical control milled devices, however, often require the use of solvents (e.g., acetonitrile) and heat to create sealed microfluidic channels and are prone to inconsistencies as a result of etching and leaking.

### SUMMARY

This section provides a general summary of the disclosure, and is not a comprehensive disclosure of its full scope or all of its features.

At least one example embodiment relates to a method for forming a weld between two thermoplastic materials.

In at least one example embodiment, the method for forming the weld between two thermoplastic materials may include contacting a laser to a precursor thermoplastic assembly consisting of a first thermoplastic material layer and a second thermoplastic material layer to cause localized melting at an interface between the first thermoplastic material layer and the second thermoplastic material layer, where the first and second thermoplastic material layers are opaque to the laser.

In at least one example embodiment, the first thermoplastic material layer may be a first optically clear thermoplastic material layer and the second thermoplastic material layer may be a second optically clear thermoplastic material layer.

In at least one example embodiment, the laser may have a speed greater than or equal to about 0.05 m/s to less than or equal to about 0.2 m/s, a power greater than or equal to about 14 W to less than or equal to about 43 W, and a density greater than or equal to about 9,800 pulses per meter to less than or equal to about 29,600 pulses per meter.

In at least one example embodiment, the laser may have a frequency greater than or equal to about 640 Hz to less than or equal to about 5,580 Hz and an energy per pulse of greater than or equal to about 0.002 J to less than or equal to about 0.07 J.

In at least one example embodiment, the laser may have a wavelength of 10.6 micrometers.

In at least one example embodiment, the first thermoplastic material layer may be a machined thermoplastic plate.

In at least one example embodiment, the second thermoplastic material layer may be a thermoplastic sheet having a thickness greater than or equal to about 40 micrometers to less than or equal to about 200 micrometers.

In at least one example embodiment, the first thermoplastic material layer may include a first thermoplastic material, the second thermoplastic material layer may include a second thermoplastic material, and the first and second thermoplastic materials may be independently selected from the group consisting of: polystyrene, cyclo-olefin-copolymer, polypropylene, polyethylene terephthalate, polyethylene, and combinations thereof.

In at least one example embodiment, the laser may be a 60-watt CO₂, 10.6 micrometer laser.

In at least one example embodiment, a speed of the 60-watt CO₂, 10.6 micrometer laser may be greater than or equal to about 25 percent of maximum to less than or equal to about 75 percent of maximum, a power of the 60-watt CO₂, 10.6 micrometer laser may be greater than or equal to about 25 percent of maximum to less than or equal to about 75 a percent of maximum, and the 60-watt CO₂, 10.6 micrometer laser may have a density of greater than or equal to about 9,842.5 pulses per meter to less than or equal to about 29,527.5 pulses per meter.

In at least one example embodiment, the method may further include, during at least a portion of the contacting of the laser to the precursor thermoplastic assembly, applying a vacuum pressure to the precursor thermoplastic assembly to maintain contact between the first thermoplastic material layer and the second thermoplastic material layer.

In at least one example embodiment, the method may further include, before the contacting of the laser to the precursor thermoplastic assembly, positioning the precursor thermoplastic assembly on a vacuum manifold, where the vacuum manifold is connected to a vacuum pump via a vacuum hose.

In at least one example embodiment, the method may further include cooling the interface to form two independent weld structures on either side of a cut zone of the laser, where the two independent weld structures are electrically isolated.

At least one example embodiment relates to another method for forming a weld between two thermoplastic materials.

In at least one example embodiment, the method for forming the weld between two thermoplastic materials may include continuously contacting a laser to a precursor thermoplastic assembly including a thermoplastic plate and a thermoplastic sheet in direct contact with a first surface of the thermoplastic plate to cause localized melting at an interface between the thermoplastic plate and the thermoplastic sheet, where the laser has a wavelength of 10.6 micrometers and the thermoplastic plate and the thermoplastic sheet are opaque to the laser. The method may further include, during at least a portion of the contacting of the laser to the precursor thermoplastic assembly, applying a vacuum pressure to the precursor thermoplastic assembly to maintain contact between the thermoplastic plate and the thermoplastic sheet.

In at least one example embodiment, the laser may have a speed greater than or equal to about 0.05 m/s to less than or equal to about 0.2 m/s, a power greater than or equal to about 14 W to less than or equal to about 43 W, a density greater than or equal to about 9,800 pulses per meter to less than or equal to about 29,600 pulses per meter, a frequency greater than or equal to about 640 Hz to less than or equal to about 5,580 Hz, and an energy per pulse of greater than or equal to about 0.002 J to less than or equal to about 0.07 J.

In at least one example embodiment, the thermoplastic plate may be a first optically clear thermoplastic material layer and the thermoplastic sheet may be a second optically clear thermoplastic material layer.

In at least one example embodiment, the thermoplastic plate may include a first thermoplastic material, the thermoplastic sheet may include a second thermoplastic material, and the first and second thermoplastic materials may be independently selected from the group consisting of: polystyrene, cyclo-olefin-copolymer, polypropylene, polyethylene terephthalate, polyethylene, and combinations thereof.

In at least one example embodiment, the thermoplastic plate may be non-electrically conductive, the thermoplastic sheet may be electrically conductive, and the method may further include cooling the interface to form a weld that electrically isolates a first portion of the thermoplastic sheet from a second portion of the thermoplastic sheet.

In at least one example embodiment, the thermoplastic plate may be a machined thermoplastic plate, and the thermoplastic sheet may have a thickness greater than or equal to about 40 micrometers to less than or equal to about 200 micrometers.

At least one example embodiment relates to another method for forming a weld between two optically clear thermoplastic materials.

In at least one example embodiment, the method for forming the weld between optically clear two thermoplastic materials may include contacting a 60-watt CO₂, 10.6 micrometer laser to a precursor thermoplastic assembly including an optically clear thermoplastic plate and an optically clear thermoplastic sheet in direct contact with a first surface of the optically clear thermoplastic plate. The laser may have a power greater than or equal to about 25 percent of maximum to less than or equal to about 75 a percent of maximum, a speed greater than or equal to about 25 percent of maximum to less than or equal to about 75 percent of maximum, and a density greater than or equal to about 9,842.5 pulses per meter to less than or equal to about 29,527.5 pulses per meter.

In at least one example embodiment, the method may further include, during at least a portion of the contacting of the laser to the precursor thermoplastic assembly, applying a vacuum pressure to the precursor thermoplastic assembly to maintain contact between the optically clear thermoplastic plate and the optically clear thermoplastic sheet.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a flowchart illustrating an example method for preparing a sealed microfluidic device in accordance with at least one example embodiment.

FIG. 2 is a cross-sectional view of an example precursor thermoplastic assembly in accordance with at least one example embodiment.

FIGS. 3A and 3B are simplified schematics detailing bonding in the instance of sealed microfluidic devices prepared in accordance with at least one example embodiment.

FIGS. 4A and 4B are cross-sectional scanning electron microscope images showing wells of the sealed microfluidic device with graphical interpretations. FIG. 4A is a 50× image. FIG. 4B is a 150× image.

FIG. 5 is a flowchart illustrating another example method for preparing a sealed microfluidic device in accordance with at least one example embodiment.

FIG. 6 is a flowchart illustrating another example method for preparing a sealed microfluidic device in accordance with at least one example embodiment.

FIGS. 7-30 are graphical demonstrations illustrating pass/fail rates for prepared polystyrene microfluidic devices, including microfluidic devices prepared in accordance with the example method of FIG. 1 and/or microfluidic devices prepared in accordance with the example method of FIG. 4 and/or microfluidic devices prepared in accordance with the example method of FIG. 5.

FIG. 31 is a graphical demonstration illustrating a liner fit relationship between speed (percent of maximum) and speed (centimeter per second).

FIG. 32 is a graphical demonstration illustrating a liner fit relationship between power (percent of maximum) and power (Watts).

FIGS. 33 and 34 are graphical demonstrations illustrating pass/fail rates for prepared cyclo-olefin-copolymer microfluidic devices, including microfluidic devices prepared in accordance with the example method of FIG. 1 and microfluidic devices prepared in accordance with the example method of FIG. 4.

FIGS. 35-41 are chromatograms for example prepared polystyrene microfluidic devices, including microfluidic devices prepared in accordance with the example method of FIG. 1 and/or microfluidic devices prepared in accordance with the example method of FIG. 4 and/or microfluidic devices prepared in accordance with the example method of FIG. 5.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers, and/or sections, these elements, components, regions, layers, and/or sections should not be limited by these terms. These terms may be only used to distinguish one element, component, region, layer or section from another region, layer, or section. Terms such as “first,” “second,” and other numerical terms when used herein do not imply a sequence or order unless clearly indicated by the context. Thus, a first element, component, region, layer, or section discussed below could be termed a second element, component, region, layer, or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Example embodiments will now be described more fully with reference to the accompanying drawings.

Microfluidics involves the manipulation of fluids at the micro or nano scale often using microchannels having at least one dimension that is less than one millimeter. Microfluidics offer mechanisms for scaling down biological experiments by many orders of magnitude, allowing users to study and manipulate fluids at the submillimeter scale. The micro-manipulation of fluids using microfluidic devices requires the consideration of differing phenomenon than that commonly considered at the macroscale. For example, known adhesive forces (e.g., van der Waals forces, electrostatic forces, surface tension, capillary forces) are often more dominant at the microscale than the relative effects of the force produced by gravity. Similarly, environmental conditions such as humidity, temperature, surface roughness, and materials often have a larger effect at the microscale than that commonly seen at the macroscale. Because of the sensitives, silicon and glass has traditionally been used to prepare single-use microfluidic devices. However, polymers, and more specifically, thermoplastics, are advancing as alternative substrates. Thermoplastics are less costly and generally easier to process with differing fabrication methods. In particular, polystyrene is a promising candidate because it is optically clear, affordable, and easily molded or processed using environmentally safe processes.

The fabrication of microfluidic devices using polymers requires bonding multiple components to create closed fluidics. Methods for welding or bonding thermoplastic components are provided herein. Methods for welding or bonding thermoplastic components for fabrication of customizable microfluidic devices are provided herein. Methods for welding or bonding optically clear thermoplastic components for fabrication of customizable microfluidic devices are provided herein. Optically clear or transparent thermoplastic components are those that allow a high degree of light transmission in the visible spectrum and enable unassisted visualization through the components. In the present instance, the optically clear thermoplastic components are material or laser opaque (i.e., less than 1% transmission) to 10.6 micrometers wavelength lasers. The use of optically clear thermoplastics allow the as-prepared microfluidic devices to be susceptible to various imaging techniques. Methods for welding or bonding laser opaque thermoplastic components for fabrication of customizable microfluidic devices are provided herein. The methods for welding or bonding thermoplastic components according to various aspects of the present disclosure do not require the use of cost-prohibited lasers (e.g., 1 micrometer lasers or 2 micrometer lasers) and/or absorption layers and/or contrasting agents and/or inconsistent solvents.

In various aspects, methods for welding or bonding thermoplastic components for fabrication of customizable microfluidic devices according to various aspects of the present disclosure may include directing infrared radiation (e.g., greater than or equal to about 3 micrometers to less than or equal to about 1,000 micrometers) onto an assembly including first and second material layers, where the infrared radiation is predominantly absorbed by the first and second materials. The methods may include controlling the intensity and duration of the infrared radiation such that the infrared radiation penetrates (or cuts) through the proximal first material layer and reaches the interface of the first material layer and the second material layer and causes localized melting at the interface. The methods may include allowing the melted interface to solidify to form single, welded structures.

In various aspects, methods for welding or bonding thermoplastic components for fabrication of customizable microfluidic devices according to various aspects of the present disclosure may include directing infrared radiation onto an assembly including first and second material layers, where the infrared radiation is predominately absorbed by the first and second materials. The methods may include controlling the intensity and duration of the infrared radiation such that it fully penetrates through the proximal first material layer and into the second material and causes localized melting at an interface between the first and second material layers. The methods may include allowing the melted interface to solidify, thereby forming two, independent, welded structures. The two welded structures may facilitate removal of one structure without disrupting the adjacent weld. The two welded structure may facilitate separation of segments of the original assembly such that electrical current cannot pass across a weld.

In various aspects, methods for welding or bonding thermoplastic components for fabrication of customizable microfluidic devices according to various aspects of the present disclosure may include using photothermal laser welding techniques to weld or bond thermoplastic components for fabrication of customizable microfluidic devices. The methods may include contacting the photothermal laser to an assembly including first and second material layers, where the laser is predominantly absorbed by the first and second materials. The methods may include controlling the intensity and duration of the laser such that the laser penetrates through the proximal first material layer and reaches the interface of the first material layer and the second material layer and causes localized melting at the interface. The methods may include allowing the melted interface to solidify to form single, welded structures.

In various aspects, methods for welding or bonding thermoplastic components for fabrication of customizable microfluidic devices according to various aspects of the present disclosure may include using photothermal laser welding techniques to weld or bond thermoplastic components for fabrication of customizable microfluidic devices. The methods may include controlling the intensity and duration of the laser such that it fully penetrates through the proximal first material layer and into the second material and causes localized melting at an interface between the first and second material layers. The methods may include allowing the melted interface to solidify, thereby forming two, independent, welded structures. The two welded structures may facilitate removal of one structure without disrupting the adjacent weld. The two welded structure may facilitate separation of segments of the original assembly such that electrical current cannot pass across a weld.

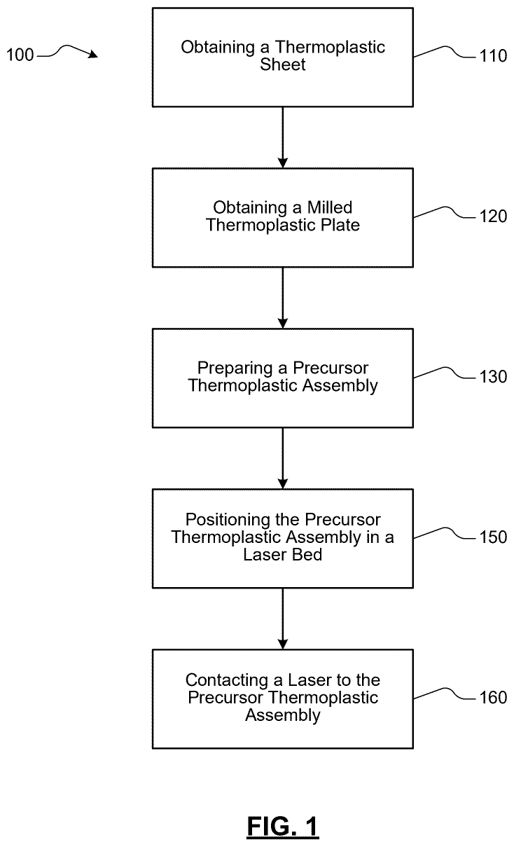

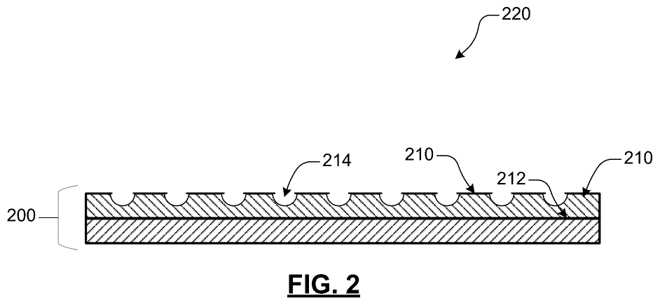

FIG. 1 is a flowchart illustrating an example method 100 for preparing a sealed microfluidic device. The method 100 includes contacting 160 a laser to a precursor thermoplastic assembly (like the precursor thermoplastic assembly 200 illustrated in FIG. 2). The laser may be continuously contacted to the precursor thermoplastic assembly 200. The laser is contacted with the precursor thermoplastic assembly 200 for a period long enough to cut through at least a portion of the precursor thermoplastic assembly and to melt at least a portion of the precursor thermoplastic assembly, as further discussed below. In at least one example embodiment, the laser may be contacted to the precursor thermoplastic assembly with a speed greater than or equal to about 0.05 m/s to less than or equal to about 0.2 m/s (e.g., greater than or equal to about 0.06 m/s to less than or equal to about 0.19 m/s or greater than or equal to about 0.065 m/s to less than or equal to about 0.189 m/s). In at least one example embodiment, the laser as contacted to the precursor thermoplastic assembly may have a power greater than or equal to about 14 W to less than or equal to about 43 W (e.g., greater than or equal to about 14.18 W to less than or equal to about 42.54 W). In at least one example embodiment, the laser as contacted to the precursor thermoplastic assembly may have a density greater than or equal to about 9,800 pulses per meter to less than or equal to about 29,600 pulses per meter (e.g., greater than or equal to about 9,842 pulses per meter to less than or equal to about 29,527 pulses per meter). In at least one example embodiment, the laser as contacted to the precursor thermoplastic assembly may have a wavelength of about 10.6 micrometers, which falls within the far infrared part of the electromagnetic spectrum (e.g., greater than or equal to about 3 micrometers to less than or equal to about 1,000 micrometers).

In at least one example embodiment, the laser as contacted to the precursor thermoplastic assembly may be a 60-watt CO₂, 10.6 micrometer laser engraver and a two-inch lens may be used. In such instances, where the 60-watt CO₂, 10.6 micrometer laser engraver is used, the laser as contacted to the precursor thermoplastic assembly may have a power greater than or equal to about 25 percent of maximum to less than or equal to about 75 a percent of maximum, where the maximum is 60 W. In such instances, where the 60-watt CO₂, 10.6 micrometer laser engraver is used, the laser may be contacted to the precursor thermoplastic assembly with a speed greater than or equal to about 25 percent of maximum to less than or equal to about 75 percent of maximum, where the maximum is 0.25 m/s. In such instances, where the 60-watt CO₂, 10.6 micrometer laser engraver is used, a density of the laser as contacted to the precursor thermoplastic assembly may have a density greater than or equal to about 250 pulses per inch (which is 9,842.5 pulses per meter) to less than or equal to about 750 pulses per inch (which is 29,527.5 pulses per meter).

FIG. 2 is a cross-sectional view of an example precursor thermoplastic assembly 200. The precursor thermoplastic assembly 200 may include a thermoplastic plate 210 and a thermoplastic sheet 220 in direct contact with thermoplastic plate 210, such that no adhesive or absorption layer is disposed between the thermoplastic plate 210 and the thermoplastic sheet 220. In at least one example embodiment the thermoplastic plate 210 may be a machined thermoplastic plate. For example, the thermoplastic plate 210 may include a first surface 212 and a machined (or second) surface 214, where the first surface 212 is substantially flat and the machined surface 214 includes a plurality of wells 214. In such instances, the thermoplastic sheet 220 may be in direct contact with the first surface 212 of the thermoplastic plate 210. In at least one example embodiment, the machined surface may be a milled surface, a three-dimensional printed surface, an injection molded surface, a thermoformed surface, an extruded surface, a vacuum formed surface, a cased surface, a compression molded surface, or any combination thereof.

The thermoplastic plate 210 may have an average thickness of greater than or equal to about 800 micrometers to less than or equal to about 1,500 micrometers. The thermoplastic sheet 220 may have an average thickness greater than or equal to about 40 micrometers to less than or equal to about 200 micrometers (e.g., greater than or equal to about 50 micrometers to less than or equal to about 190 micrometers, about 50 micrometers, about 125 micrometers, or about 190 micrometers). The thermoplastic plate 210 and the thermoplastic sheet 220 may include the same or different thermoplastic materials. The thermoplastic materials for the thermoplastic plate and the thermoplastic sheet 220 should both be material opaque to the laser. In at least one example embodiment, the thermoplastic plate 210 and the thermoplastic sheet 220 should be optically clear thermoplastic material layers. In at least one example embodiment, the thermoplastic plate 210 and the thermoplastic sheet 220 may include thermoplastic materials independently selected from the group consisting of: polystyrene, cyclo-olefin-copolymer, polypropylene, polyethylene terephthalate, polyethylene, and combinations thereof. In at least one example embodiment, the thermoplastic plate 210 may be a FALCON® 96-Well Clear Flat Bottom TC-Treated Culture Microplate. In at least one example embodiment, one or more surfaces of the thermoplastic sheet 220 may be pre-treated. For example, both major surfaces of the thermoplastic sheet 220 may be pre-treated to increase the hydrophilicity of the material, for example, to improve cell attachment.

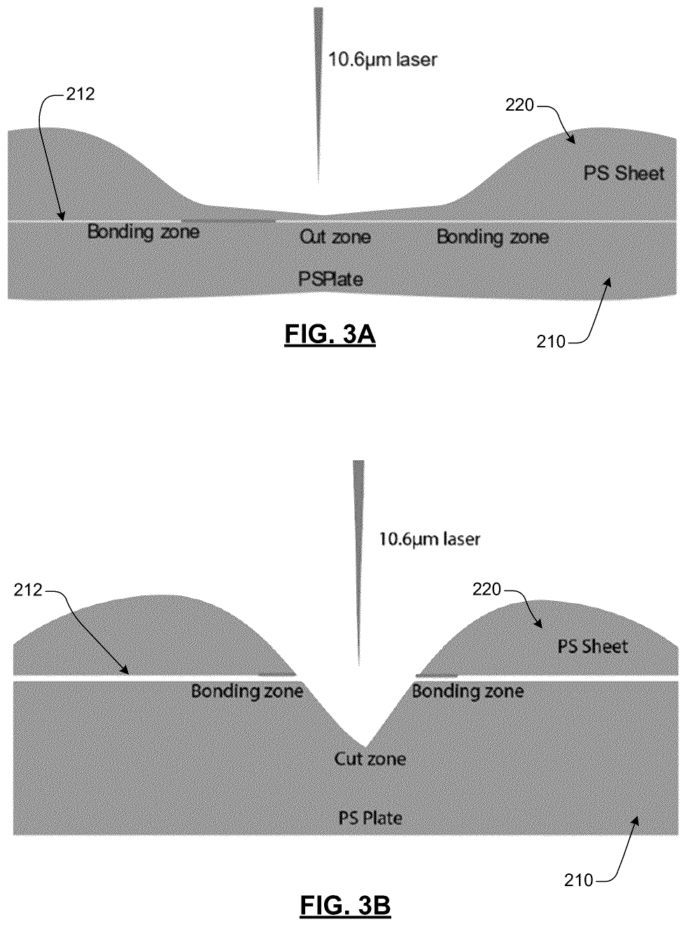

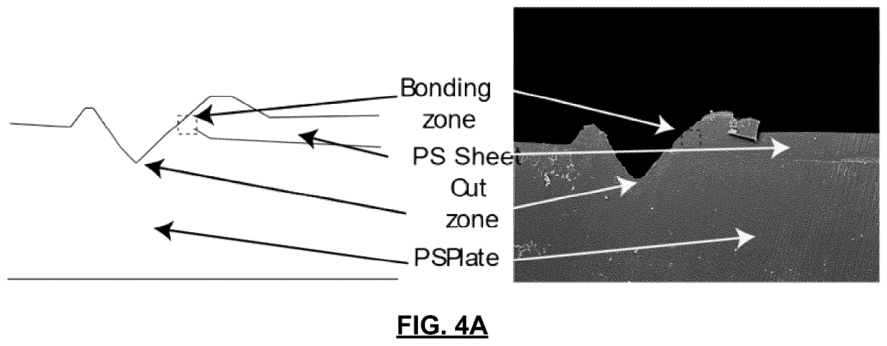

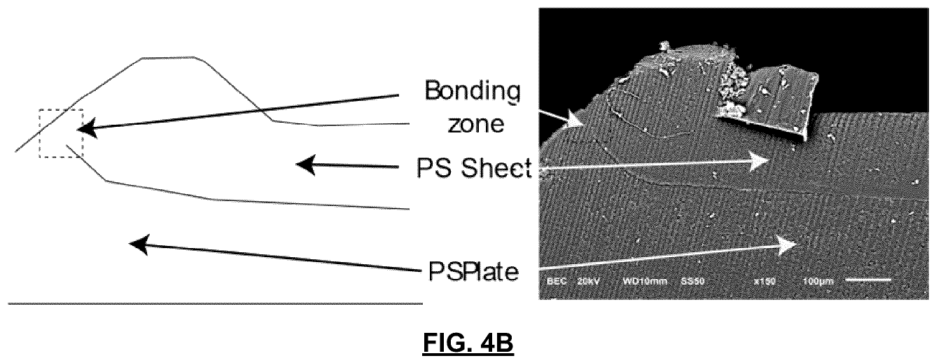

With renewed reference to FIG. 1, during the contacting 160, the laser is contact with the thermoplastic sheet 220 side of the precursor thermoplastic assembly 200. In at least one example embodiment, the laser passes through the thermoplastic sheet 220 and is absorbed by the thermoplastic plate 210 such that the thermoplastic sheet 220 is physically welded to the thermoplastic plate 210. For example, FIGS. 3A and 3B are simplified schematics detailing the bonding of the thermoplastic sheet 220 and the thermoplastic plate 210. Further, FIGS. 4A and 4B are cross-sectional scanning electron microscope images with graphical interpretations showing the physical weld of an example sealed microfluidic device prepared in accordance with various aspects of method 100. As illustrated, the contacting 160 of the laser to the precursor thermoplastic assembly 200 creates two welds-one on each side of the contact point (or cut zone) of the laser. The creation of the two welds, allows excess material to be easily removed from the prepared sealed microfluidic device without disturbing the sealed portions, for example, when electrical interference is a concern or isolation is needed, such as in the instance of trans-epithelial electrical resistance assay. The welds are not connected by the bonded material. For example, as illustrated in FIG. 4A, the thermoplastic sheet is missing from one side of the weld but present in the other.

With renewed reference to FIG. 1, in at least one example embodiment, the method 100 may include, prior to the contacting 160, positioning the precursor thermoplastic assembly 200 within the laser bed. In at least one example embodiment, the method 100 may include, prior to the positioning 150, preparing 130 the thermoplastic assembly 200. Preparing the thermoplastic assembly 200 may include disposing the thermoplastic sheet 220 on or near the machined side 212 of the thermoplastic plate 210. In at least one example embodiment, the method 100 may include, prior to the preparing 130 of the thermoplastic assembly 200, obtaining 120 the thermoplastic plate 210. In at least one example embodiment, the method 100 may include, prior to the preparing 130 of the thermoplastic assembly 200, obtaining 110 the thermoplastic sheet 220.

Although not illustrated, it should be appreciated that, in various example embodiments, the method 100 may include milling a precursor thermoplastic plate to preparing the thermoplastic plate 210. Preparing the thermoplastic plate 210 may include obtaining a thermoplastic blank and machining or milling the thermoplastic blank, using, for example, computer numerical control machining. Although not illustrated, it should be appreciated that, in various example embodiments, the method 100 may include cooling and solidifying the as-contacted thermoplastic assembly. Although not illustrated, it should be appreciated that, in various example embodiments, the method 100 may include removing the sealed microfluidic device from the laser bed after the contacting 160. Although not illustrated, it should be appreciated that, in various example embodiments, the method 100 may include cutting or shaping the precursor thermoplastic assembly 200 and/or the thermoplastic plate 210 and/or the thermoplastic sheet 220 and/or the sealed microfluidic device.

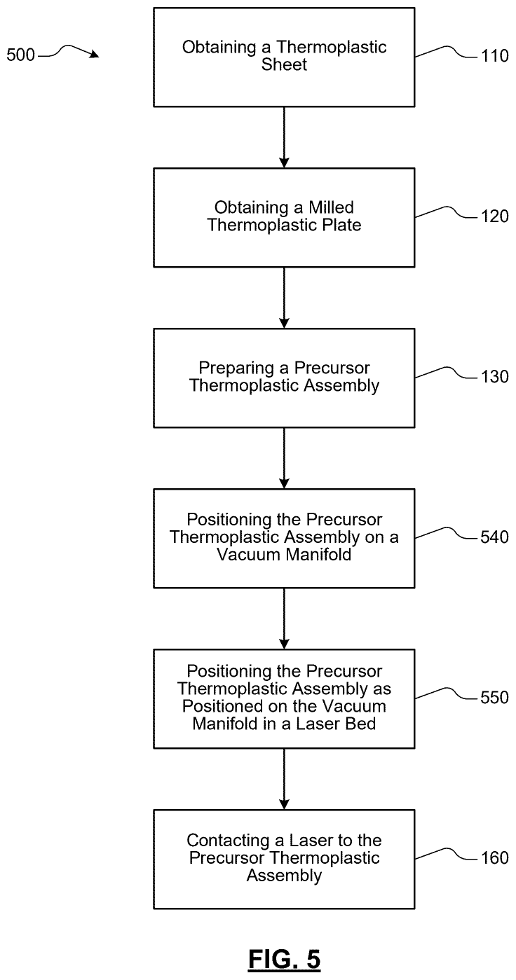

FIG. 5 is a flowchart illustrating another example method 500 for preparing a sealed microfluidic device. The method 500 may be the same as the method 100 illustrated in FIG. 1 except that the method 500 includes using a vacuum system. For example, the method 500 may include, prior to the contacting 160, positioning 540 the precursor thermoplastic assembly 200 on a vacuum manifold and positioning 550 the precursor thermoplastic assembly 200 as positioned on the vacuum manifold in the laser bed, where the vacuum manifold is connected to a vacuum pump using a vacuum hose. The vacuum system may help to maintain tight contact between the thermoplastic sheet 220 and the thermoplastic plate 210. The vacuum system may be used to apply a vacuum pressure at a constant level. In at least one example embodiment, the applied vacuum pressure may be about-0.79 bar.

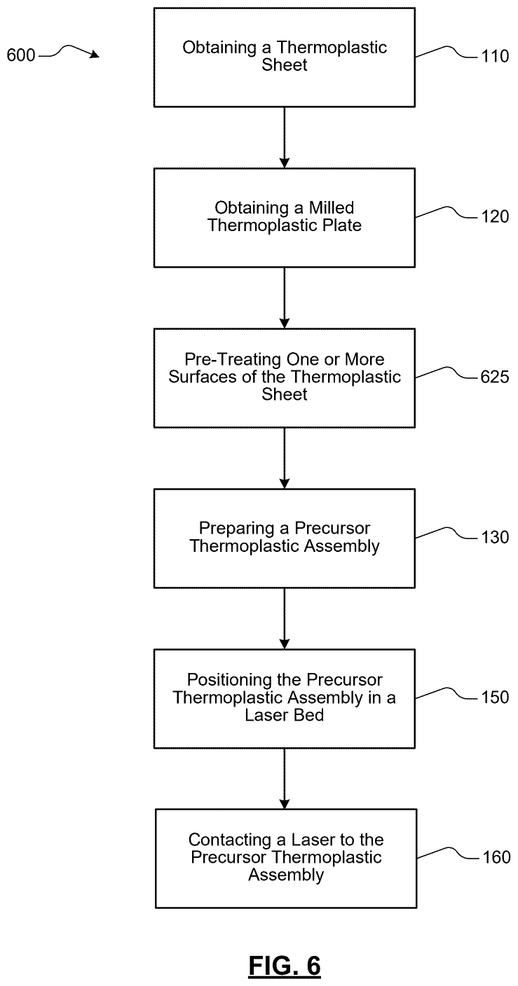

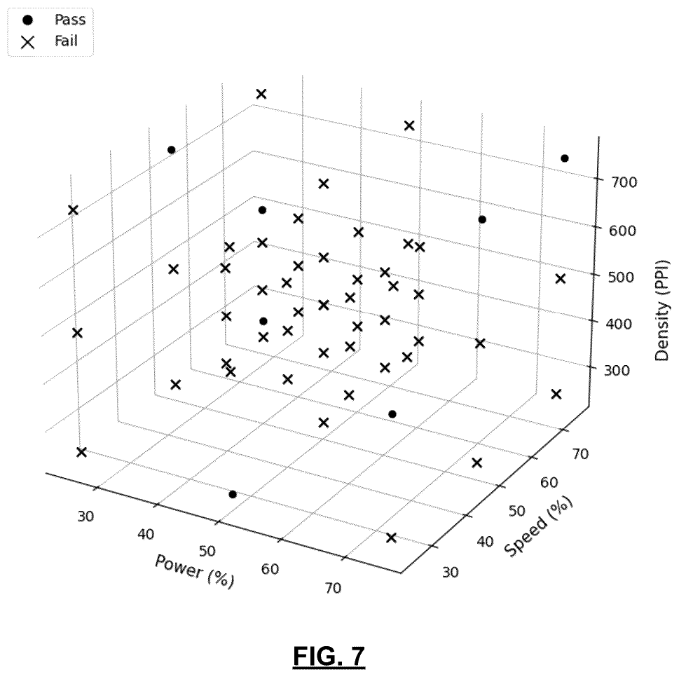

FIG. 6 is a flowchart illustrating another example method 600 for preparing a sealed microfluidic device. The method 600 may be the same as the method 100 illustrated in FIG. 1 and/or the method 500 illustrated in FIG. 5 except that the method includes, prior to the contacting 160, pre-treating one or more surfaces of the thermoplastic sheet. For example, in at least one example embodiment, both major surfaces of the thermoplastic sheet 220 may be pre-treated to increase the hydrophilicity of the material, for example, to improve cell attachment. In at least one example embodiment, the one or more surfaces of the thermoplastic sheet may be pre-treated using oxygen gas plasma in a plasma treater with a plasma time of greater than or equal to about 1 minute to less than or equal to about 10 minutes (e.g., about 3 minutes) and an oxygen flow greater than or equal to about 10 cc/minutes to less than or equal to about 20 cc/minutes (e.g., about 15 cc/minute).

Certain features of the current technology are further illustrated in the following non-limiting examples.

### Examples 1-3

Example microfluidic devices were prepared in accordance with various aspects of the above detailed methods. For example, the following table summarizes the preparation details for certain microfluidic devices, where the thicknesses of the thermoplastic sheets are varied, the plasma treatments of the thermoplastic sheets are varied, and the focal length of the different laser treatments are altered.

| | Thick- | Surface | | |
|---|---|---|---|---|
| | ness | Treatment | Focal Length | Pass/Fail |
| Example 1A | 50 μm | None | 5.08 cm | Pass: 7 |
| | | | (in focus) | Fail: 47 |
| Example 1B | 50 μm | None | 4.1 cm | Pass: 21 |
| | | | (out of focus) | Fail: 33 |
| Example 1C | 50 μm | Oxygen/Plasma | 5.08 cm | Pass: 15 |
| | | | (in focus) | Fail:39 |
| Example 1D | 50 μm | Oxygen/Plasma | 4.1 cm | Pass: 22 |
| | | | (out of focus) | Fail: 32 |
| Example 2A | 125 μm | None | 5.08 cm | Pass: 47 |
| | | | (in focus) | Fail: 7 |
| Example 2B | 125 μm | None | 4.1 cm | Pass: 41 |
| | | | (out of focus) | Fail: 13 |
| Example 2C | 125 μm | Oxygen/Plasma | 5.08 cm | Pass: 50 |
| | | | (in focus) | Fail: 4 |
| Example 2D | 125 μm | Oxygen/Plasma | 4.1 cm | Pass: 53 |
| | | | (out of focus) | Fail: 1 |
| Example 3A | 190 μm | None | 5.08 cm | Pass: 54 |
| | | | (in focus) | Fail: 0 |
| Example 3B | 190 μm | None | 4.1 cm | Pass: 52 |
| | | | (out of focus) | Fail: 2 |
| Example 3C | 190 μm | Oxygen/Plasma | 5.08 cm | Pass: 36 |
| | | | (in focus) | Fail: 18 |
| Example 3D | 190 μm | Oxygen/Plasma | 4.1 cm | Pass: 37 |
| | | | (out of focus) | Fail: 17 |

In each of the above noted examples, a precursor thermoplastic assembly including a machined polystyrene thermoplastic plate and a polystyrene thermoplastic sheet was contacted with a 60-watt CO₂, 10.6 micrometer laser engraver using a two-inch lens to prepared sealed microfluidic devices. In the instances of Examples 1C, 1D, 2C, 2D, 3C, and 3D, both major surfaces of the respective thermoplastic sheet were subjected to surface treatments. For example, the surfaces were treated using oxygen gas plasma in a plasma treater with a plasma time of about 3 minutes and at 15 cc/minute. The pass/fail of the prepared sealed microfluidic devices was determined using seep tests. The seep tests included pressurizing the welds, adding about 300 mmHg of air to the weld using a hand operated pump, and positioning a three-dimensional printer adaptor to re-seal the weld. If any pressure loss was observed after one minute, the prepare sealed microfluidic device failed. If pressure was maintained, the prepared sealed microfluidic device passed.

FIG. 7 is a graphical demonstration illustrating the pass/fail for Example 1A, where the x₁-axis is power (percent of maximum), the x₂-axis is speed (percent of maximum), and the y-axis is density (pulses per inch). FIG. 7 is a graphical demonstration illustrating the pass/fail for Example 1A, where the x-axis is frequency (Hz) and the y-axis is energy per pulse (J). As illustrated, 54 prepared sealed microfluidic devices of Example 1A were subjected to different laser powers, speeds, and densities, and the sealed microfluidic devices of Example 1A had an overall pass rate of 12.9%.

For a first set of the prepared sealed microfluidic devices including 27 prepared sealed microfluidic devices of Example 1A, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 1A, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

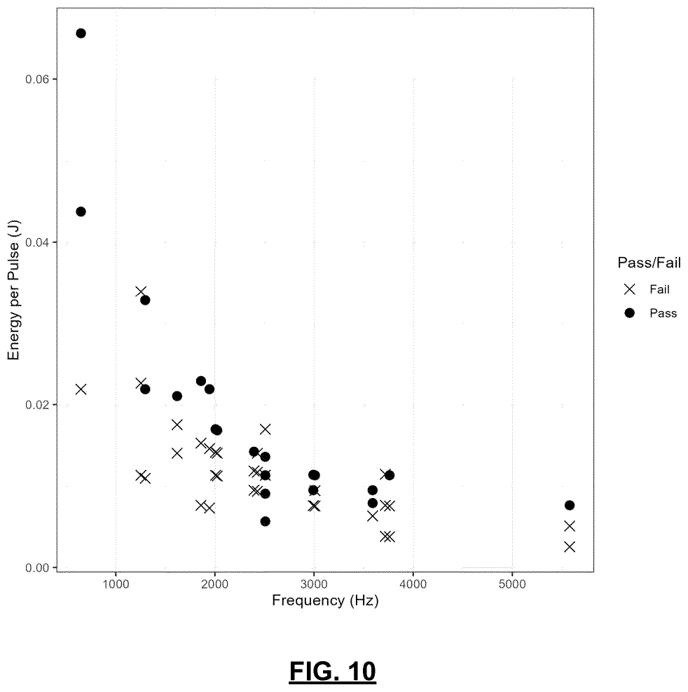

FIG. 9 is a graphical demonstration illustrating the pass/fail for Example 1B, where the x₁-axis is power (percent of maximum), the x₂-axis is speed (percent of maximum), and the y-axis is density (pulses per inch). FIG. 10 is a graphical demonstration illustrating the pass/fail for Example 1B, where the x-axis is frequency (Hz) and the y-axis is energy per pulse (J). As illustrated, 54 prepared sealed microfluidic devices of Example 1B were subjected to different laser powers, speeds, and densities, and the sealed microfluidic devices of Example 1B had an overall pass rate of 38.8%.

For a first set of the prepared sealed microfluidic devices including 27 prepared sealed microfluidic devices of Example 1B, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 1B, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

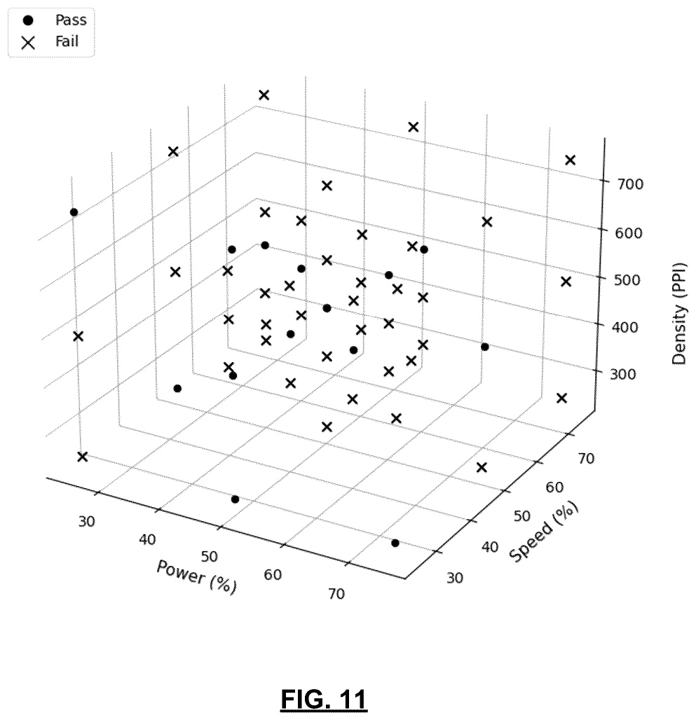

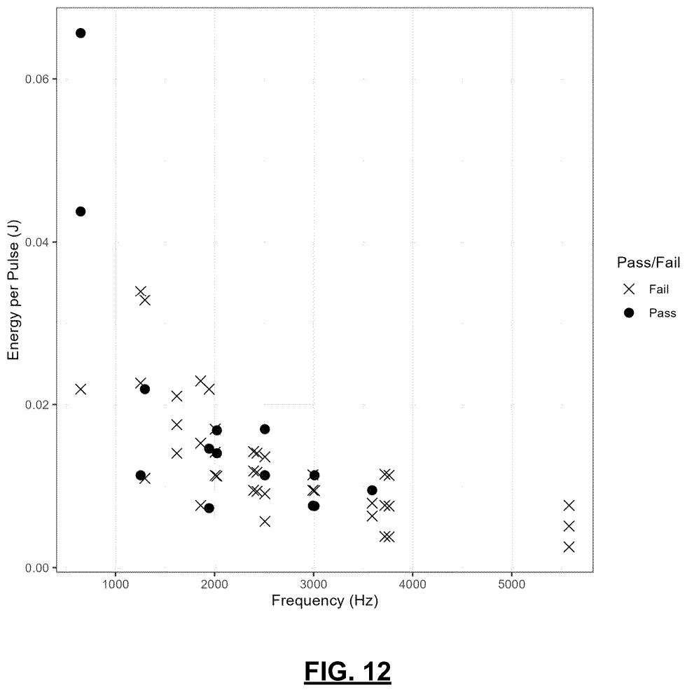

FIG. 11 is a graphical demonstration illustrating the pass/fail for Example 1C, where the x₁-axis is power (percent of maximum), the x₂-axis is speed (percent of maximum), and the y-axis is density (pulses per inch). FIG. 12 is a graphical demonstration illustrating the pass/fail for Example 1C, where the x-axis is frequency (Hz) and the y-axis is energy per pulse (J). As illustrated, 54 prepared sealed microfluidic devices of Example 1C were subjected to different laser powers, speeds, and densities, and the sealed microfluidic devices of Example 1C had an overall pass rate of 27.7%.

For a first set of the prepared sealed microfluidic devices including 27 prepared sealed microfluidic devices of Example 1C, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 1C, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

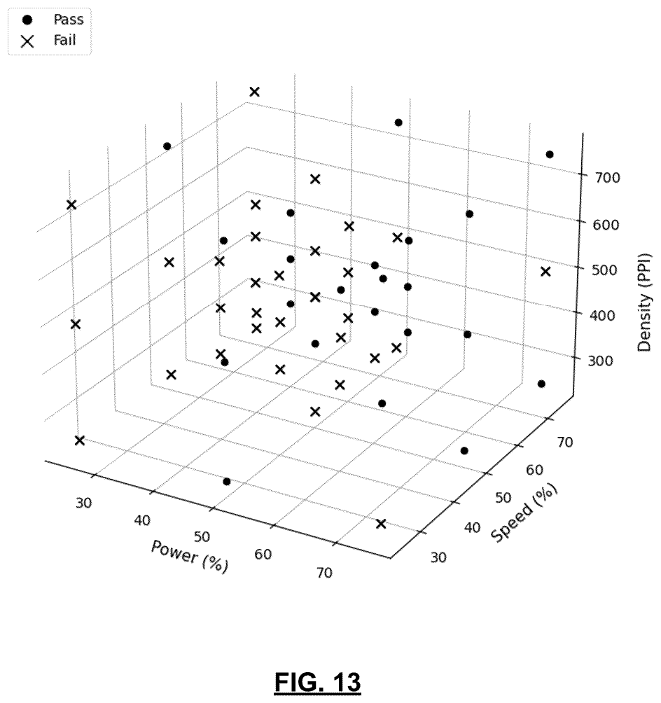

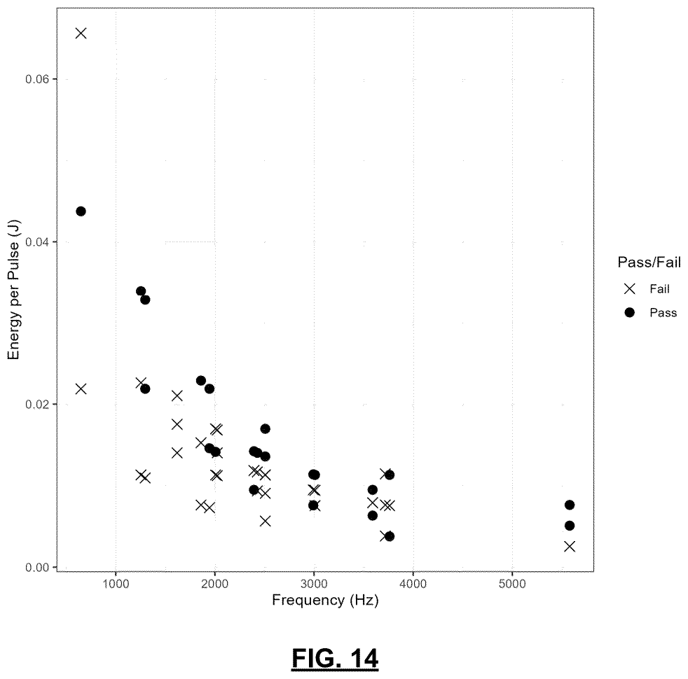

FIG. 13 is a graphical demonstration illustrating the pass/fail for Example 1D, where the x₁-axis is power (percent of maximum), the x₂-axis is speed (percent of maximum), and the y-axis is density (pulses per inch). FIG. 14 is a graphical demonstration illustrating the pass/fail for Example 1D, where the x-axis is frequency (Hz) and the y-axis is energy per pulse (J). As illustrated, 54 prepared sealed microfluidic devices of Example 1D were subjected to different laser powers, speeds, and densities, and the sealed microfluidic devices of Example 1D had an overall pass rate of 40.7%.

For a first set of the prepared sealed microfluidic devices including 27 prepared sealed microfluidic devices of Example 1D, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 1D, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

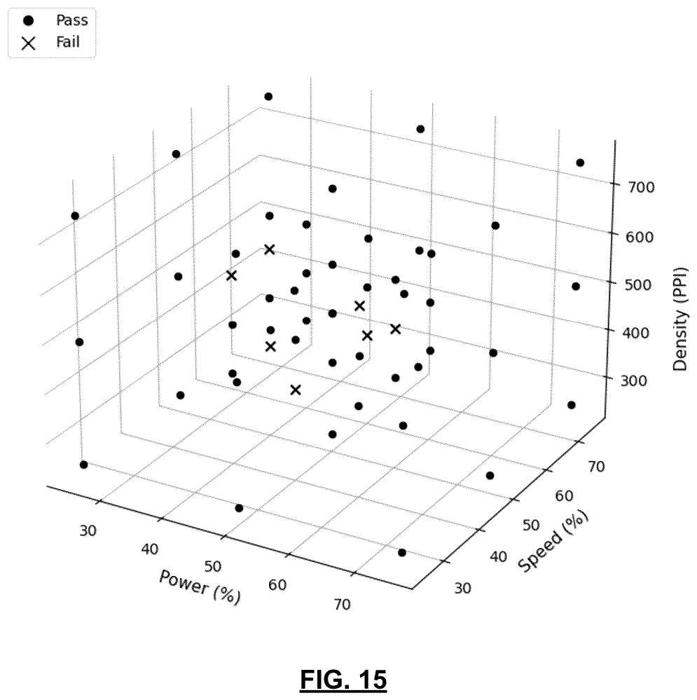

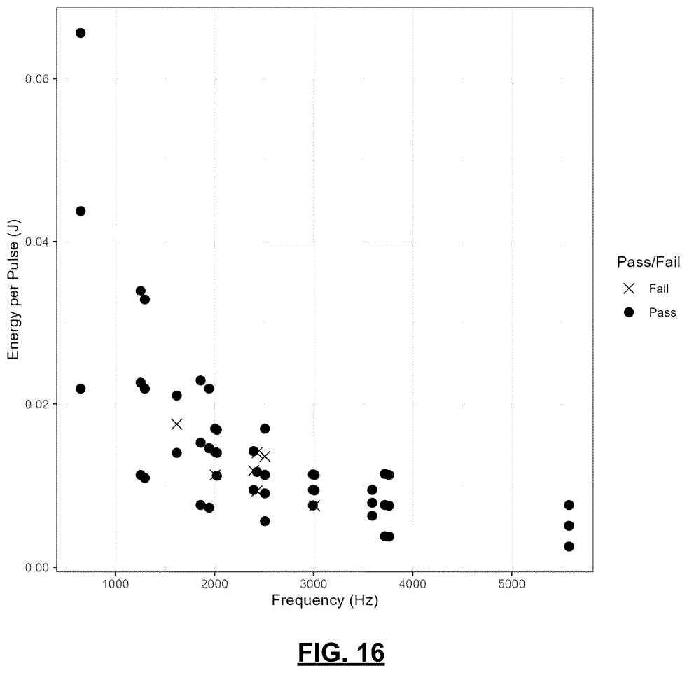

FIG. 15 is a graphical demonstration illustrating the pass/fail for Example 2A, where the x₁-axis is power (percent of maximum), the x₂-axis is speed (percent of maximum), and the y-axis is density (pulses per inch). FIG. 16 is a graphical demonstration illustrating the pass/fail for Example 2A, where the x-axis is frequency (Hz) and the y-axis is energy per pulse (J). As illustrated, 54 prepared sealed microfluidic devices of Example 2A were subjected to different laser powers, speeds, and densities, and the sealed microfluidic devices of Example 2A had an overall pass rate of 87%.

For a first set of the prepared sealed microfluidic devices including 27 prepared sealed microfluidic devices of Example 2A, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 2A, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

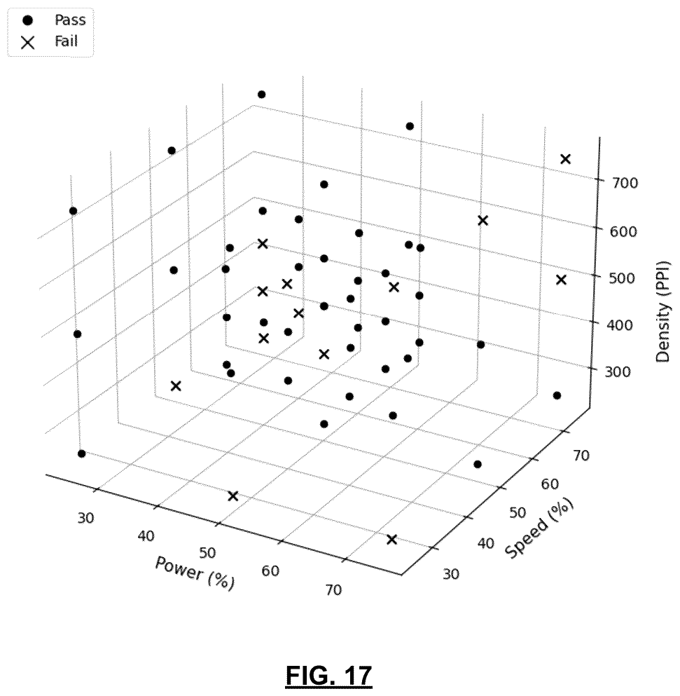

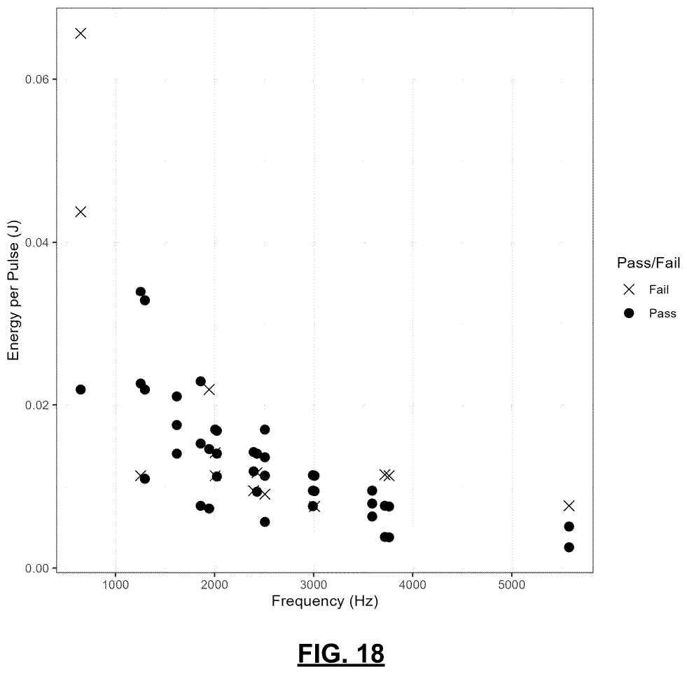

FIG. 17 is a graphical demonstration illustrating the pass/fail for Example 2B, where the x₁-axis is power (percent of maximum), the x₂-axis is speed (percent of maximum), and the y-axis is density (pulses per inch). FIG. 18 is a graphical demonstration illustrating the pass/fail for Example 2B, where the x-axis is frequency (Hz) and the y-axis is energy per pulse (J). As illustrated, 54 prepared sealed microfluidic devices of Example 2B were subjected to different laser powers, speeds, and densities, and the sealed microfluidic devices of Example 2B had an overall pass rate of 75.9%.

For a first set of the prepared sealed microfluidic devices including 27 prepared sealed microfluidic devices of Example 2B, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 2B, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

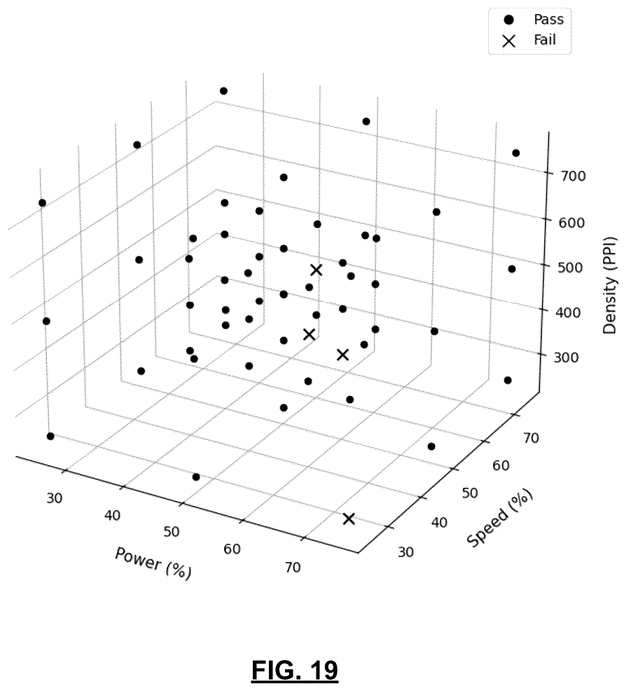

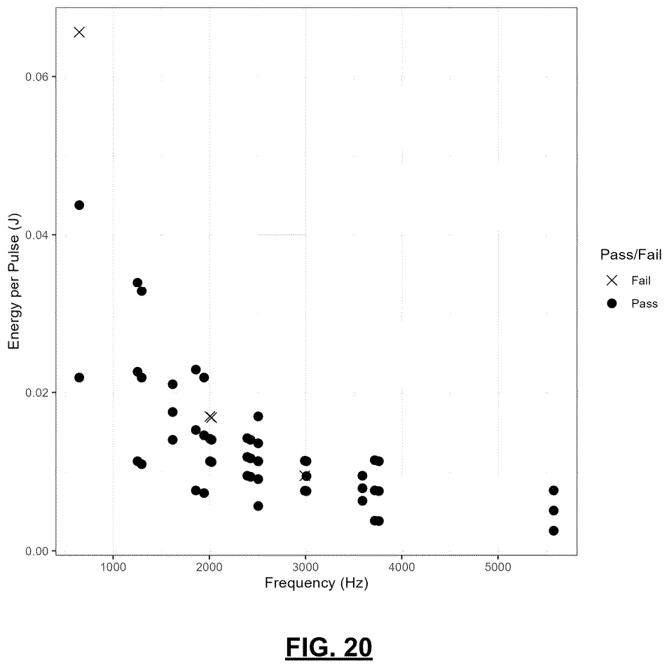

FIG. 19 is a graphical demonstration illustrating the pass/fail for Example 2C, where the x₁-axis is power (percent of maximum), the x₂-axis is speed (percent of maximum), and the y-axis is density (pulses per inch). FIG. 20 is a graphical demonstration illustrating the pass/fail for Example 2C, where the x-axis is frequency (Hz) and the y-axis is energy per pulse (J). As illustrated, 54 prepared sealed microfluidic devices of Example 2C were subjected to different laser powers, speeds, and densities, and the sealed microfluidic devices of Example 2C had an overall pass rate of 92.6%.

For a first set of the prepared sealed microfluidic devices including 27 prepared sealed microfluidic devices of Example 2C, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 2C, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

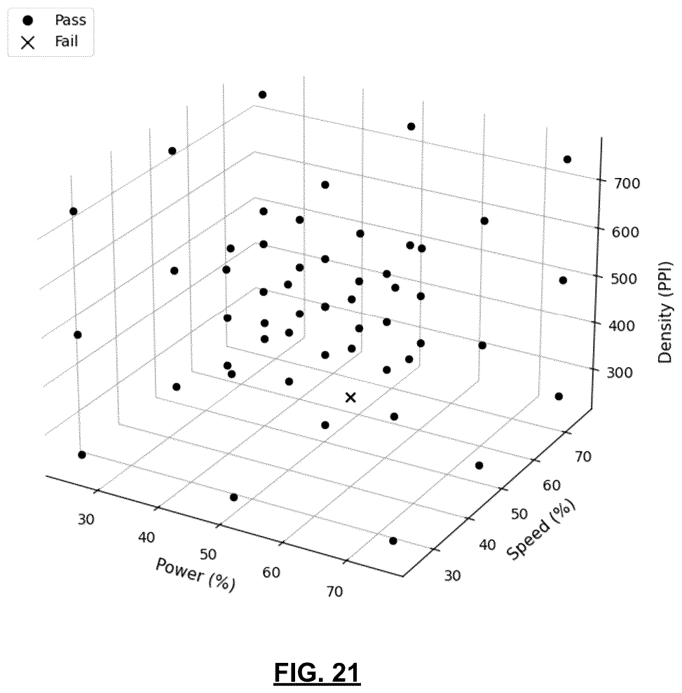

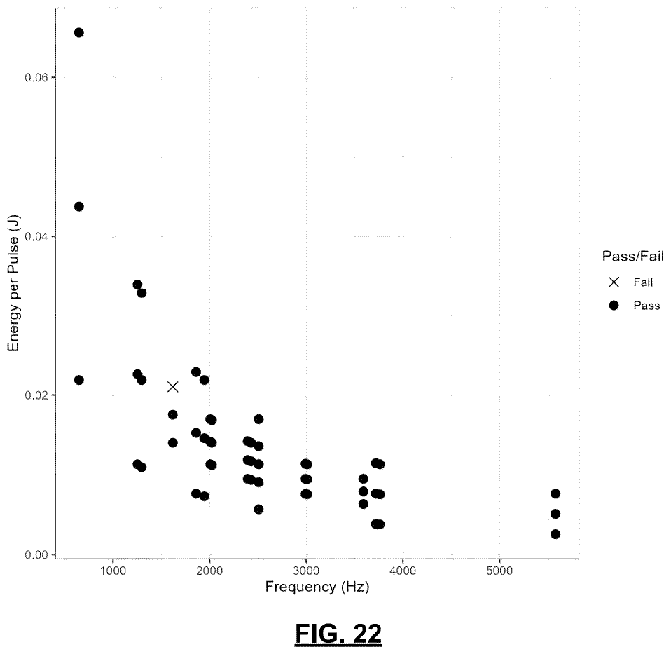

FIG. 21 is a graphical demonstration illustrating the pass/fail for Example 2D, where the x₁-axis is power (percent of maximum), the x₂-axis is speed (percent of maximum), and the y-axis is density (pulses per inch). FIG. 22 is a graphical demonstration illustrating the pass/fail for Example 2D, where the x-axis is frequency (Hz) and the y-axis is energy per pulse (J). As illustrated, 54 prepared sealed microfluidic devices of Example 2D were subjected to different laser powers, speeds, and densities, and the sealed microfluidic devices of Example 2D had an overall pass rate of 98.1%.

For a first set of the prepared sealed microfluidic devices including 27 prepared sealed microfluidic devices of Example 2D, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 2D, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

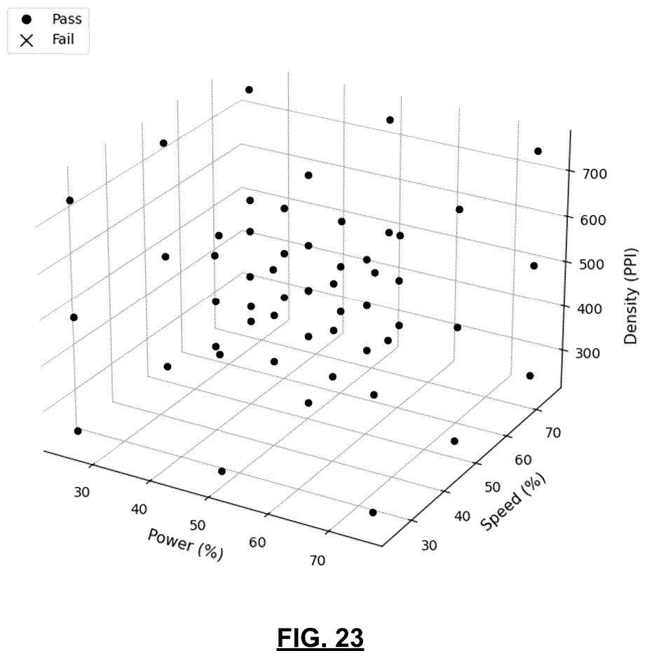

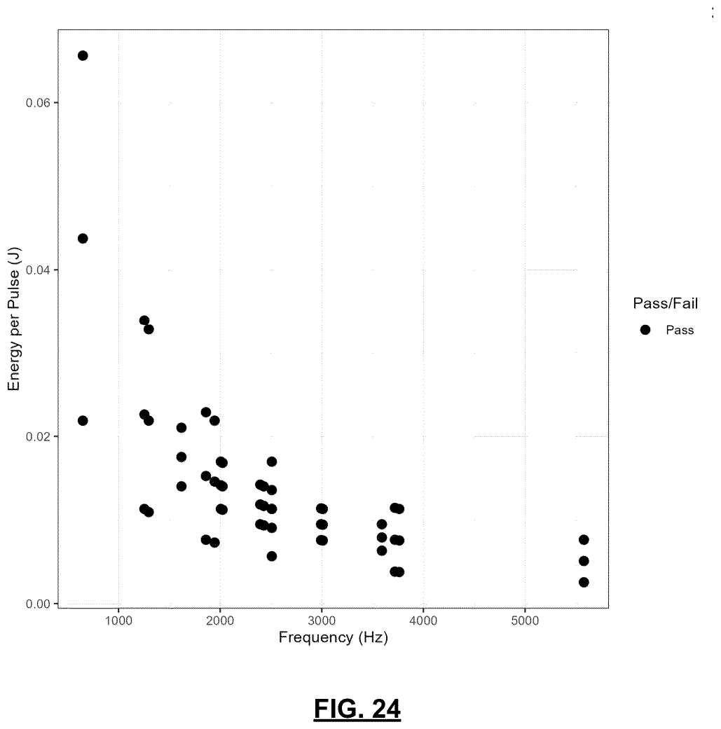

FIG. 23 is a graphical demonstration illustrating the pass/fail for Example 3A, where the x₁-axis is power (percent of maximum), the x₂-axis is speed (percent of maximum), and the y-axis is density (pulses per inch). FIG. 24 is a graphical demonstration illustrating the pass/fail for Example 3A, where the x-axis is frequency (Hz) and the y-axis is energy per pulse (J). As illustrated, 54 prepared sealed microfluidic devices of Example 3A were subjected to different laser powers, speeds, and densities, and the sealed microfluidic devices of Example 3A had an overall pass rate of 100%.

For a first set of the prepared sealed microfluidic devices including 27 prepared sealed microfluidic devices of Example 3A, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 3A, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

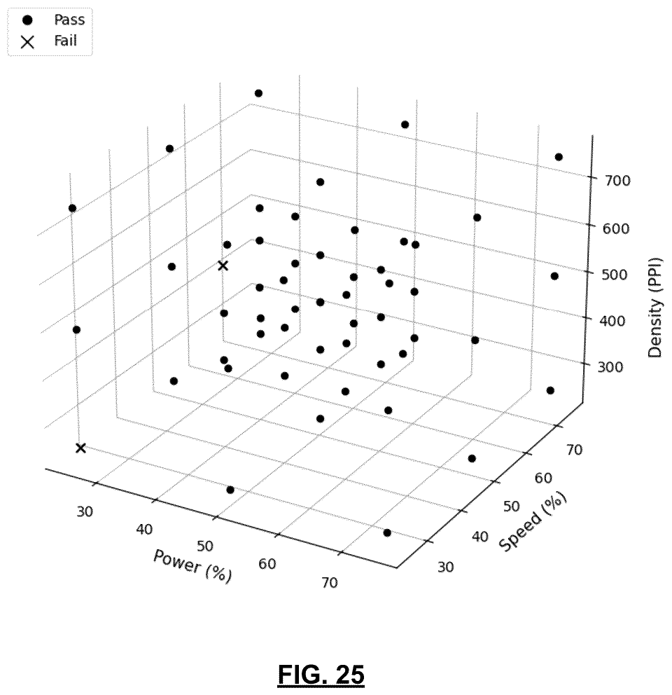

FIG. 25 is a graphical demonstration illustrating the pass/fail for Example 3B, where the x₁-axis is power (percent of maximum), the x₂-axis is speed (percent of maximum), and the y-axis is density (pulses per inch). FIG. 26 is a graphical demonstration illustrating the pass/fail for Example 3B, where the x-axis is frequency (Hz) and the y-axis is energy per pulse (J). As illustrated, 54 prepared sealed microfluidic devices of Example 3B were subjected to different laser powers, speeds, and densities, and the sealed microfluidic devices of Example 3B had an overall pass rate of 96.3%.

For a first set of the prepared sealed microfluidic devices including 27 prepared sealed microfluidic devices of Example 3B, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 3B, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

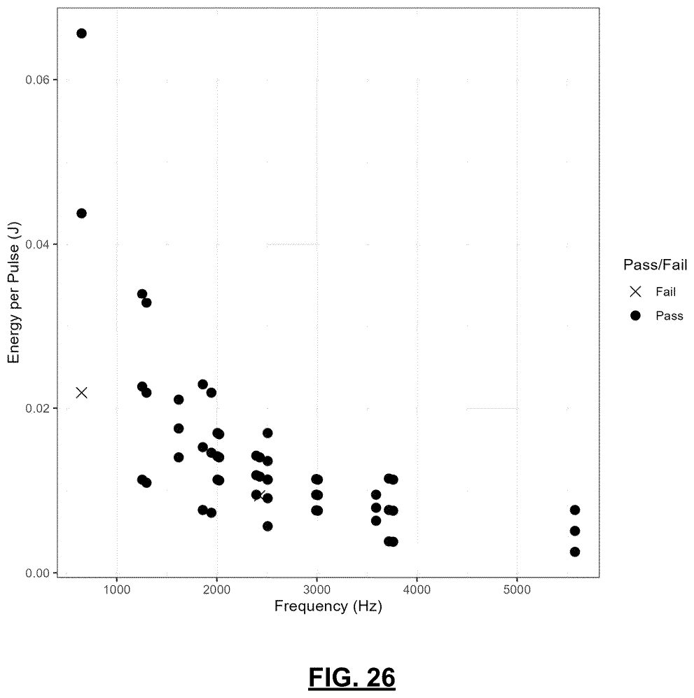

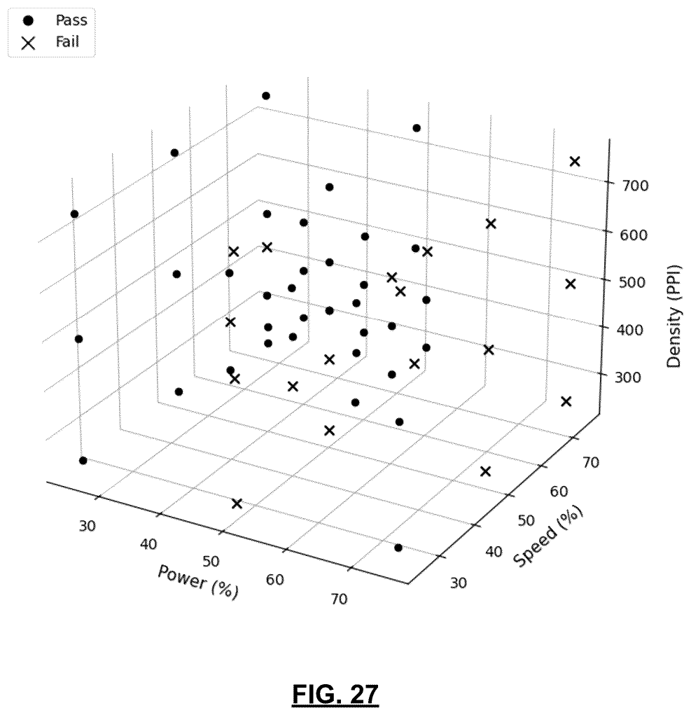

FIG. 27 is a graphical demonstration illustrating the pass/fail for Example 3C, where the x₁-axis is power (percent of maximum), the x₂-axis is speed (percent of maximum), and the y-axis is density (pulses per inch). FIG. 28 is a graphical demonstration illustrating the pass/fail for Example 3C, where the x-axis is frequency (Hz) and the y-axis is energy per pulse (J). As illustrated, 54 prepared sealed microfluidic devices of Example 3C were subjected to different laser powers, speeds, and densities, and the sealed microfluidic devices of Example 3C had an overall pass rate of 66.7%.

For a first set of the prepared sealed microfluidic devices including 27 prepared sealed microfluidic devices of Example 3C, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 3C, the laser as contacted to the precursor thermoplastic assembly included powers and speeds that were varied by 25% and density by 250 pulse per inch covering a range of 25 percent of maximum to 75% of maximum for power and speed and a range of 250 pulses per inch to 750 pulses per inch for density.

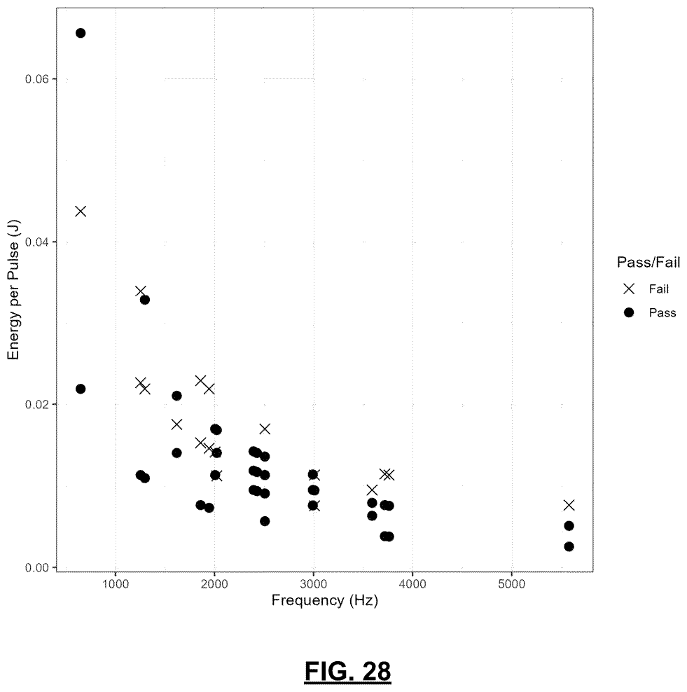

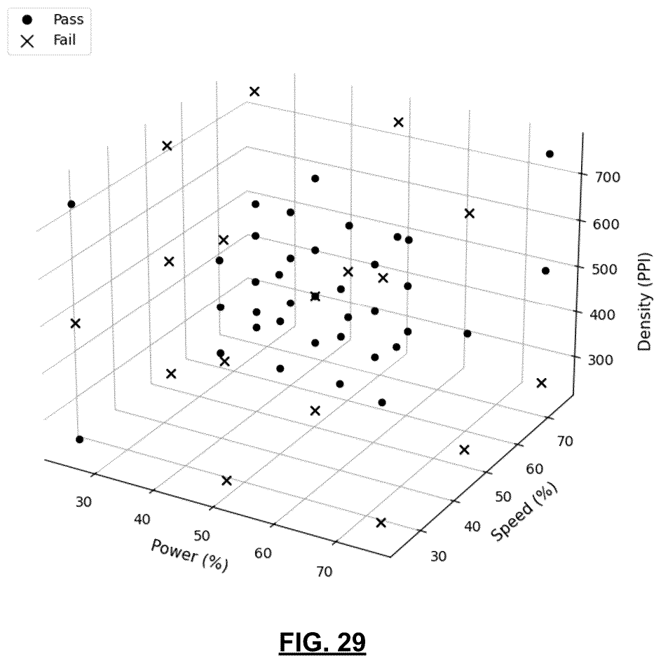

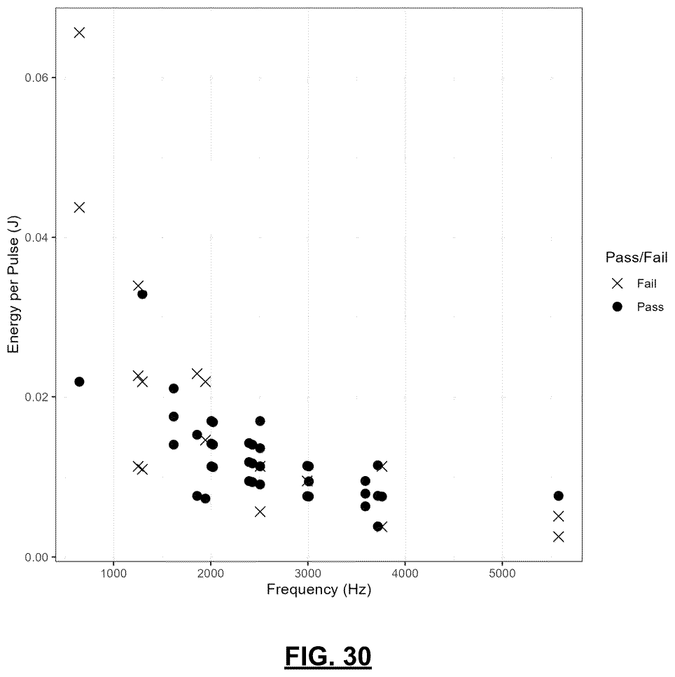

FIG. 29 is a graphical demonstration illustrating the pass/fail for Example 3D, where the x₁-axis is power (percent of maximum), the x₂-axis is speed (percent of maximum), and the y-axis is density (pulses per inch). FIG. 30 is a graphical demonstration illustrating the pass/fail for Example 3D, where the x-axis is frequency (Hz) and the y-axis is energy per pulse (J). As illustrated, 54 prepared sealed microfluidic devices of Example 3D were subjected to different laser powers, speeds, and densities, and the sealed microfluidic devices of Example 3D had an overall pass rate of 68.5%.

For a first set of the prepared sealed microfluidic devices including 27 prepared sealed microfluidic devices of Example 3D, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 3D, the laser as contacted to the precursor thermoplastic assembly included powers and speeds that were varied by 25% and density by 250 pulse per inch covering a range of 25 percent of maximum to 75 percent of maximum for power and speed and a range of 250 pulses per inch to 750 pulses per inch for density.

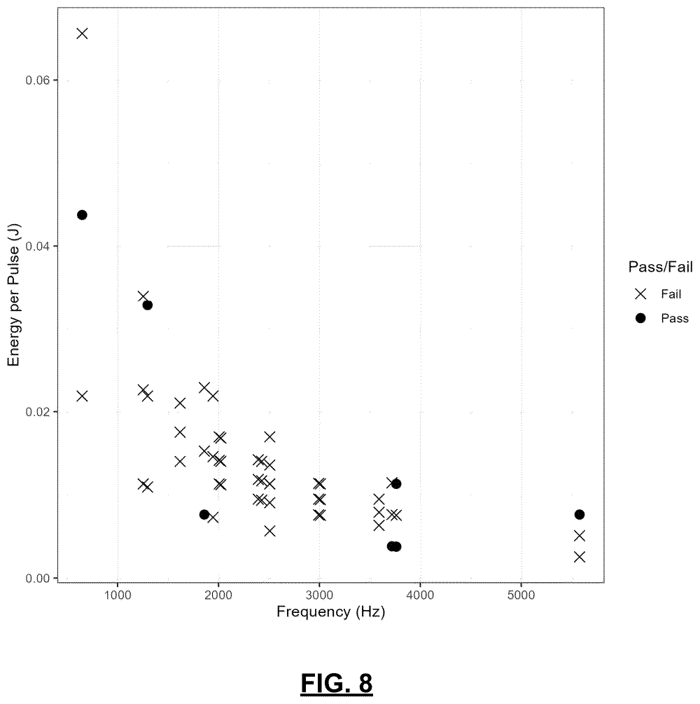

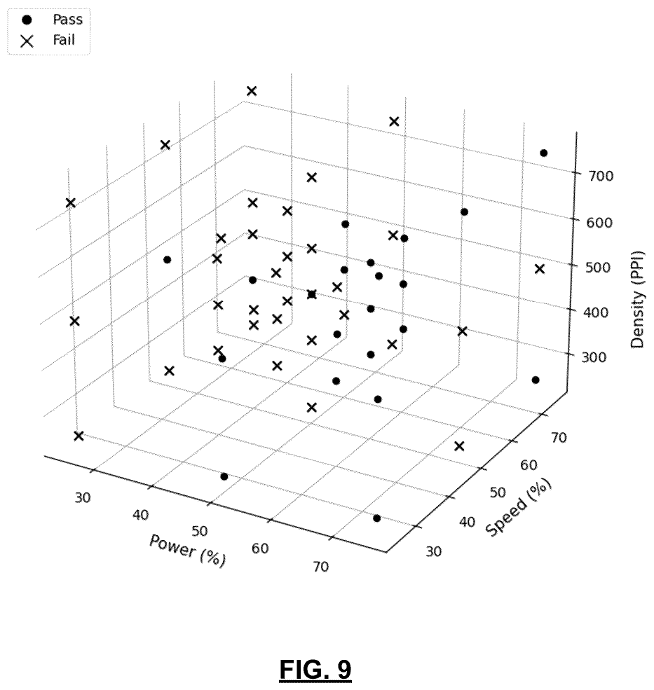

As seen in the graphical demonstrations of FIGS. 7-30, the pass/fail rate generally improved as the thickness of the thermoplastic sheet increased and also generally where the thermoplastic sheet does not undergo a surface treatment and also generally where a focal length for the laser is 5.08 centimeters. Further, out of the seventy-eight different power, speed, density combinations, six combinations passed in every instance, including: (1) power: 60 percent of maximum, speed: 50 percent, density: 500 pulses per inch; (2) power: 60 percent of maximum, speed: 50 percent of maximum, density: 600 pulses per inch; (3) power: 60 percent of maximum, speed: 60 percent of maximum, density: 400 pulses per inch; (4) power: 60 percent of maximum, speed: 60 percent of maximum, density: 500 pulses per inch; (5) power: 60 percent of maximum, speed: 50 percent of maximum, density: 600 pulses per inch; and (6) power: 75 percent of maximum, speed: 25 percent of maximum, density: 500 pulses per inch.

For comparison, FIG. 31 is a graphical demonstration showing the liner fit relationship between speed (percent of maximum) and speed (centimeter per second), where the x-axis is speed (percent of maximum) and the y-axis is speed (centimeter per second). For example, in at least one example embodiment, the relationship between speed (percent of maximum) and the speed (centimeter per second) may be summarized by equation [1] as shown below.

$$Y = 0.2461 x + 0.4356 \qquad [ 1 ]$$

In at least one example embodiment, the laser as contacted to the precursor thermoplastic assembly in the instances of Examples 1A-3D may have a speed greater than or equal to about 0.05 m/s to less than or equal to about 0.2 m/s (e.g., greater than or equal to about 0.06 m/s to less than or equal to about 0.19 m/s or greater than or equal to about 0.065 m/s to less than or equal to about 0.189 m/s).

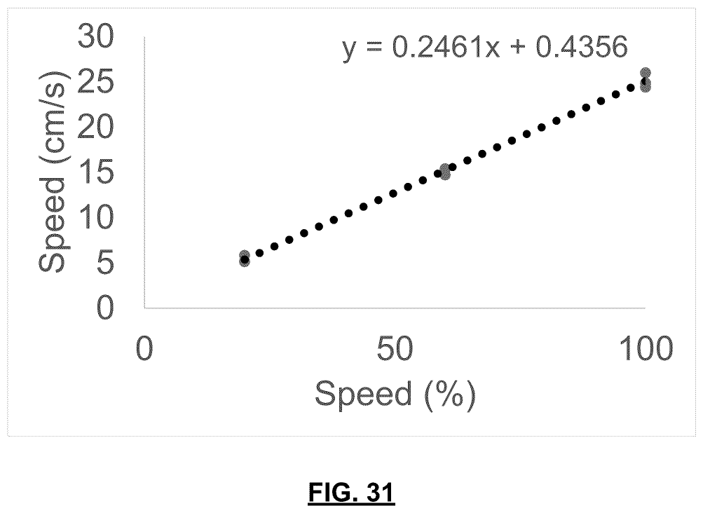

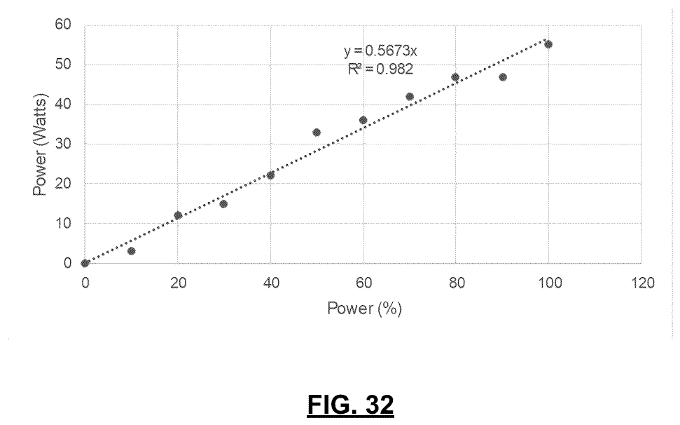

For comparison, FIG. 32 is a graphical demonstration showing the liner fit relationship between power (percent of maximum) and power (Watts), where the x-axis is the speed (percent of maximum) and the y-axis is power (Watts). For example, in at least one example embodiment, the relationship between the power (percent of maximum) and the power (Watts) may be summarized by equation [2] as shown below.

$$Y = 0.5673 x \qquad [ 2 ]$$

In at least one example embodiment, the laser as contacted to the precursor thermoplastic assembly in the instances of Examples 1A-3D may have a power greater than or equal to about 14 W to less than or equal to about 43 W (e.g., greater than or equal to about 14.18 W to less than or equal to about 42.54 W).

The frequency and energy per pulse may be determined in the instances of each example by first determining a total time (T), determining a total number (n) of pulses, and determining the duration of each pulse (K). The total time (T) may be determined using equation [3] as shown below, where the length (L) is a constant of 4 centimeter

$$T = \frac{L}{S} \qquad [ 3 ]$$

The total number (n) of pulses may be determined using equation [4] as shown below, where D is the density (pulses per meter).

$$n = D L \qquad [ 4 ]$$

The duration of each pulse (K) may be determined using equation [5] as shown below.

$$K = \frac{T}{n} \qquad [ 5 ]$$

The frequency (F) may in turn be determined using equation [6] as shown below. F 1 K

$$F = \frac{1}{K} \qquad [ 6 ]$$

The energy per pulse (E) may in turn determined using equation [7] as shown below.

$$E = P K \qquad [ 7 ]$$

In at least one example embodiment, the laser as contacted to the precursor thermoplastic assembly in the instances of Examples 1A-3D may have a frequency greater than or equal to about 640 Hz to less than or equal to about 5,580 Hz (e.g., greater than or equal to about 648 Hz to less than or equal to about 5,579 Hz) and energy per pulse of greater than or equal to about 0.002 J to less than or equal to about 0.07 J (e.g., greater than or equal to about 0.0025 J to less than or equal to about 0.066 J).

### Example 4

Example microfluidic devices were prepared in accordance with various aspects of the above detailed methods. For example, a precursor thermoplastic assembly including a machined cyclo-olefin-copolymer thermoplastic plate and a cyclo-olefin-copolymer thermoplastic sheet having a thickness of 140 micrometers was contacted with a 60-watt CO₂, 10.6 micrometer laser engraver using a two-inch lens to prepared sealed microfluidic devices. FIG. 33 is a graphical demonstration illustrating the pass/fail for Example 4, where the x₁-axis is power (percent of maximum), the x₂-axis is speed (percent of maximum), and the y-axis is density (pulses per inch). FIG. 34 is a graphical demonstration illustrating the pass/fail for Example 4, where the x-axis is frequency (Hz) and the y-axis is energy per pulse (J). The pass/fail of the prepared sealed microfluidic devices was determined using a seep test. The seep tests included pressurizing the welds, adding about 300 mmHg of air to the weld using a hand operated pump, and positioning a three-dimensional printer adaptor to re-seal the weld. If any pressure loss was observed after one minute, the prepare sealed microfluidic device failed. If pressure was maintained, the prepared sealed microfluidic device passed.

As illustrated, 54 prepared sealed microfluidic devices of Example 4 were subjected to different laser powers, speeds, and densities, and the sealed microfluidic devices of Example 4 had an overall pass rate of 20.3%. For a first set of the prepared sealed microfluidic devices including 27 prepared sealed microfluidic devices of Example 4, the laser as contacted to the precursor thermoplastic assembly included powers and speeds that were varied by 10% and density by 100 pulses per inch covering a range of 40 percent of maximum to 60 percent of maximum for power and speed and a range of 400 pulses per inch to 600 pulses per inch for density. For a second set of the prepared sealed microfluidic devices including 27 prepared sealed microfluidic devices of Example 4, the laser as contacted to the precursor thermoplastic assembly included powers and speeds that were varied by 25% and density by 250 pulse per inch covering a range of 25 percent of maximum to 75 percent of maximum for power and speed and a range of 250 pulses per inch to 750 pulses per inch for density. For both sets, the laser was out of focus with a focal length of 4.1 centimeters.

### Example 5

Example microfluidic devices were prepared in accordance with various aspects of the above detailed methods. For example, the following table summarizes the preparation details for certain microfluidic devices, where a precursor thermoplastic assembly including a machined polystyrene thermoplastic plate (96 wells) and a polystyrene thermoplastic sheet was contacted with a 60-watt CO₂, 10.6 micrometer laser engraver using a two-inch lens and with a focal length of 4.1 centimeters to prepared sealed microfluidic devices but with different powers, speeds, and densities.

| | Power | Speed | Density |
|---|---|---|---|
| | (Percent of | (Percent of | (Pulses |
| | Maximum) | Maximum) | Per Inch) |
| Example 5A | 20 | 60 | 650 |
| Example 5B | 20 | 80 | 750 |
| Example 5C | 50.5 | 50 | 512 |
| Example 5D | 30 | 35 | 750 |

Each of the examples included three separately prepared microfluidic devices. After the preparation of Examples 5A-5D, samples for analyzing mass spectrometry were collected through extraction in 100% acetonitrile. For example, the prepared microfluidic devices were added to 100 microliters of acetonitrile and maintained in the acetonitrile for 20 seconds. Afterwards, the resulting acetonitrile for each of the three separately prepared microfluidic devices were pooled for each of Examples 5A-5D, such that each sample included 300 microliters. Three controls were similarly prepared: a first control including 300 microliters of 100% acetonitrile, a second control including 300 microliters of acetonitrile after contacted with a clean, non-plasma polystyrene sheet for 20 seconds, and a third control including 300 microliters of acetonitrile after contacted with a clean, machined and unbonded polystyrene plate having 96 wells for 20 seconds.

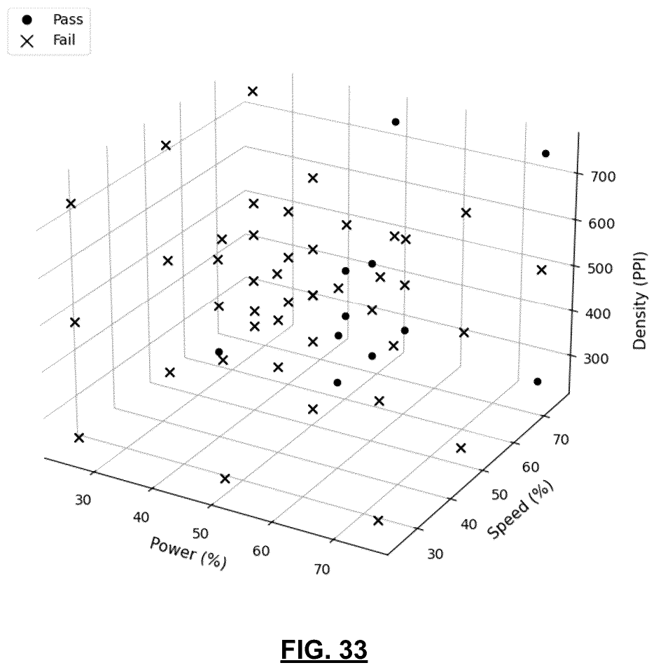

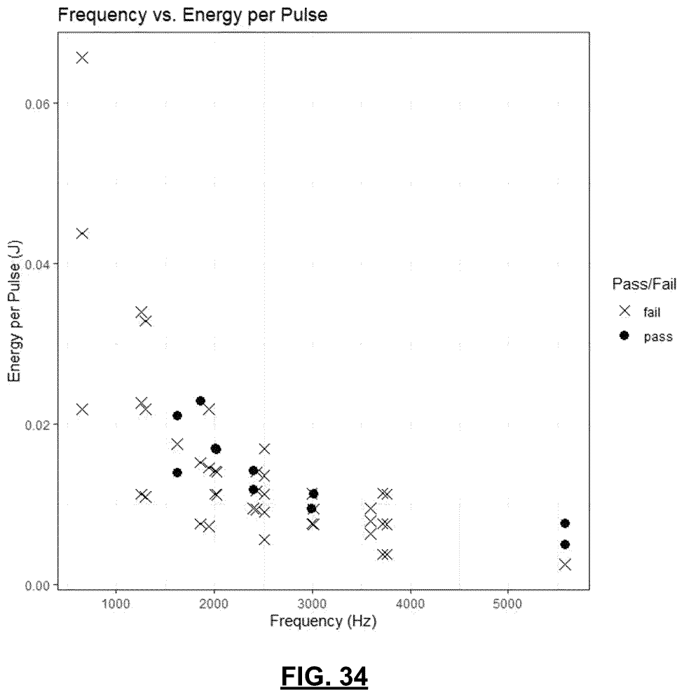

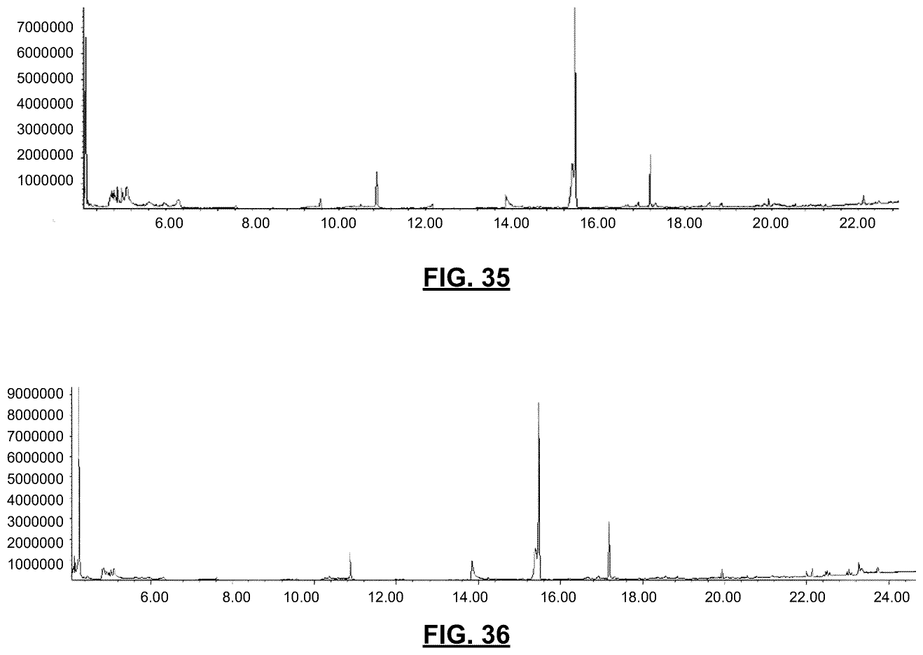

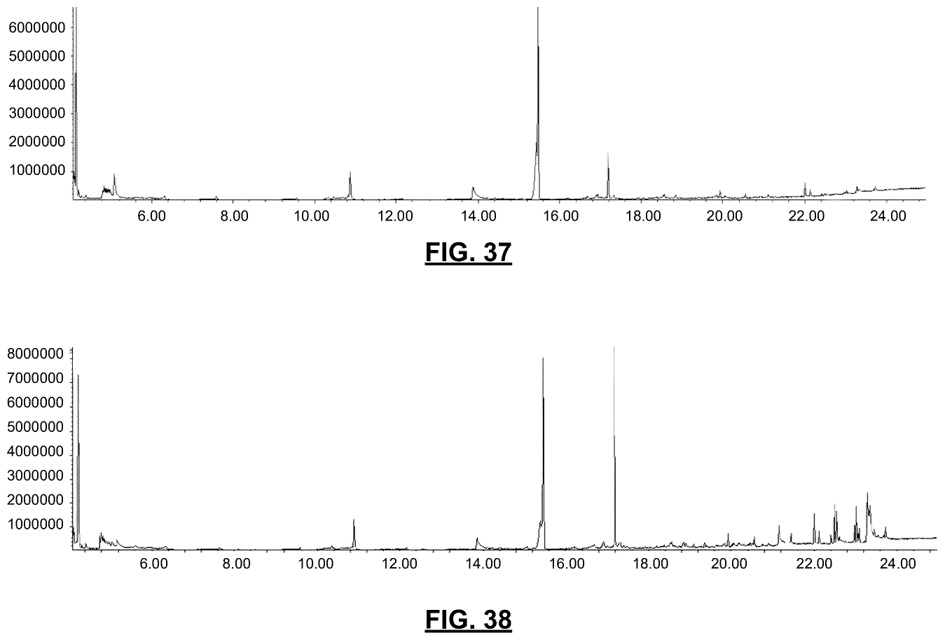

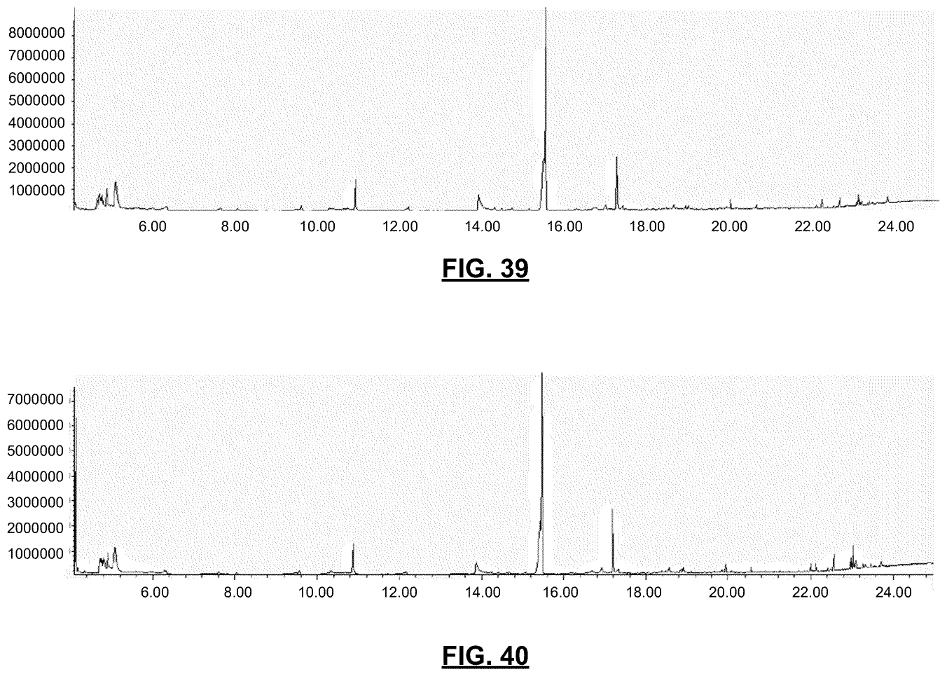

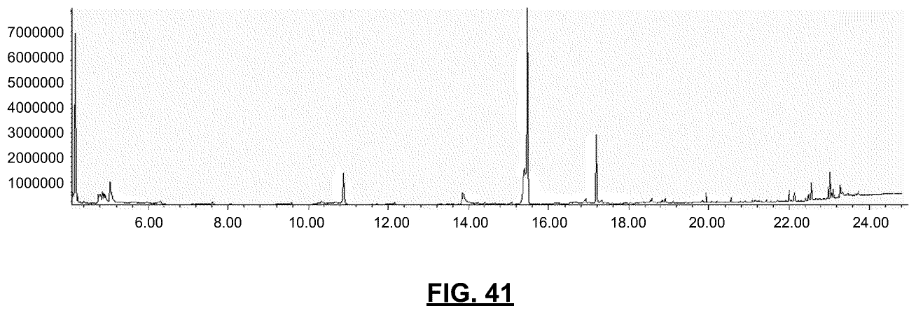

FIG. 35 is a chromatogram for the first prepared control. FIG. 36 is a chromatogram for the second prepared control. FIG. 37 is a chromatogram for the third prepared control. FIG. 38 is a chromatogram for Example 5A. FIG. 39 is a chromatogram for Example 5B. FIG. 40 is a chromatogram for Example 5C. FIG. 41 is a chromatogram for Example 5D. The chromatograms confirm that a physical weld is created between the thermoplastic sheet and the thermoplastic plate of the respective precursor thermoplastic assemblies during the formation of the microfluidic devices.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for forming a weld between two thermoplastic materials, the method comprising:
contacting a laser to a precursor thermoplastic assembly consisting of a first thermoplastic material layer and a second thermoplastic material layer to cause localized melting at an interface between the first thermoplastic material layer and the second thermoplastic material layer, the first and second thermoplastic material layers being opaque to the laser.

2. The method of claim 1, wherein
the first thermoplastic material layer is a first optically clear thermoplastic material layer, and
the second thermoplastic material layer is a second optically clear thermoplastic material layer.

3. The method of claim 1, wherein the laser has a speed greater than or equal to about 0.05 m/s to less than or equal to about 0.2 m/s, a power greater than or equal to about 14 W to less than or equal to about 43 W, and a density greater than or equal to about 9,800 pulses per meter to less than or equal to about 29,600 pulses per meter.

4. The method of claim 1, wherein the laser has a frequency greater than or equal to about 640 Hz to less than or equal to about 5,580 Hz and an energy per pulse of greater than or equal to about 0.002 J to less than or equal to about 0.07 J.

5. The method of claim 1, wherein the laser has a wavelength of 10.6 micrometers.

6. The method of claim 1, wherein the first thermoplastic material layer is a machined thermoplastic plate.

7. The method of claim 6, wherein the second thermoplastic material layer is a thermoplastic sheet having a thickness greater than or equal to about 40 micrometers to less than or equal to about 200 micrometers.

8. The method of claim 1, wherein
the first thermoplastic material layer includes a first thermoplastic material,
the second thermoplastic material layer includes a second thermoplastic material, and
the first and second thermoplastic materials are independently selected from the group consisting of: polystyrene, cyclo-olefin-copolymer, polypropylene, polyethylene terephthalate, polyethylene, and combinations thereof.

9. The method of claim 1, wherein the laser is a 60-watt CO₂, 10.6 micrometer laser.

10. The method of claim 9, wherein
a speed of the 60-watt CO₂, 10.6 micrometer laser is greater than or equal to about 25 percent of maximum to less than or equal to about 75 percent of maximum,
a power of the 60-watt CO₂, 10.6 micrometer laser is greater than or equal to about 25 percent of maximum to less than or equal to about 75 a percent of maximum, and
the 60-watt CO₂, 10.6 micrometer laser has a density of greater than or equal to about 9,842.5 pulses per meter to less than or equal to about 29,527.5 pulses per meter.

11. The method of claim 1, wherein the method further comprises:
during at least a portion of the contacting of the laser to the precursor thermoplastic assembly, applying a vacuum pressure to the precursor thermoplastic assembly to maintain contact between the first thermoplastic material layer and the second thermoplastic material layer.

12. The method of claim 11, wherein the method further comprises:
before the contacting of the laser to the precursor thermoplastic assembly, positioning the precursor thermoplastic assembly on a vacuum manifold, the vacuum manifold being connected to a vacuum pump via a vacuum hose.

13. The method of claim 1, wherein the method further comprises:
cooling the interface to form two independent weld structures on either side of a cut zone of the laser, the two independent weld structures being electrically isolated.

14. A method for forming a weld between two thermoplastic materials, the method comprising:
continuously contacting a laser to a precursor thermoplastic assembly including a thermoplastic plate and a thermoplastic sheet in direct contact with a first surface of the thermoplastic plate to cause localized melting at an interface between the thermoplastic plate and the thermoplastic sheet, the laser having a wavelength of 10.6 micrometers, the thermoplastic plate and the thermoplastic sheet being opaque to the laser; and
during at least a portion of the contacting of the laser to the precursor thermoplastic assembly, applying a vacuum pressure to the precursor thermoplastic assembly to maintain contact between the thermoplastic plate and the thermoplastic sheet.

15. The method of claim 14, wherein the laser has a speed greater than or equal to about 0.05 m/s to less than or equal to about 0.2 m/s, a power greater than or equal to about 14 W to less than or equal to about 43 W, a density greater than or equal to about 9,800 pulses per meter to less than or equal to about 29,600 pulses per meter, a frequency greater than or equal to about 640 Hz to less than or equal to about 5,580 Hz, and an energy per pulse of greater than or equal to about 0.002 J to less than or equal to about 0.07 J.

16. The method of claim 14, wherein
the thermoplastic plate is a first optically clear thermoplastic material layer, and
the thermoplastic sheet is a second optically clear thermoplastic material layer.

17. The method of claim 14, wherein
the thermoplastic plate includes a first thermoplastic material,
the thermoplastic sheet includes a second thermoplastic material, and
the first and second thermoplastic materials are independently selected from the group consisting of: polystyrene, cyclo-olefin-copolymer, polypropylene, polyethylene terephthalate, polyethylene, and combinations thereof.

18. The method of claim 14, wherein
the thermoplastic plate is non-electrically conductive,
the thermoplastic sheet is electrically conductive, and
the method further comprises:
cooling the interface to form a weld that electrically isolates a first portion of the thermoplastic sheet from a second portion of the thermoplastic sheet.

19. A method for preparing a sealed microfluidic device by forming a weld between two optically clear thermoplastic materials, the method comprising:
contacting a 60-watt CO₂, 10.6 micrometer laser to a precursor thermoplastic assembly including an optically clear thermoplastic plate and an optically clear thermoplastic sheet in direct contact with a first surface of the optically clear thermoplastic plate, the laser having a power greater than or equal to about 25 percent of maximum to less than or equal to about 75 a percent of maximum, a speed greater than or equal to about 25 percent of maximum to less than or equal to about 75 percent of maximum, and a density greater than or equal to about 9,842.5 pulses per meter to less than or equal to about 29,527.5 pulses per meter.

20. The method of claim 19, wherein the method further comprises:
during at least a portion of the contacting of the laser to the precursor thermoplastic assembly, applying a vacuum pressure to the precursor thermoplastic assembly to maintain contact between the optically clear thermoplastic plate and the optically clear thermoplastic sheet.
